(19) United States
(12) Patent Application Publication
(10) Pub. No.: US 2025/0384197 A1
(43) Pub. Date: Dec. 18, 2025

(54) RECONFIGURABLE SECURITY FABRIC FOR SECURING DIGITAL CIRCUIT DESIGNS

(71) Applicant: University of Florida Research Foundation, Incorporated, Gainesville, FL (US)

(72) Inventors: Swarup Bhunia, Gainesville, FL (US); Aritra Dasgupta, Gainesville, FL (US); Atri Chatterjee, Gainesville, FL (US); Sudipta Paria, Gainesville, FL (US); Habibur Rahaman, Gainesville, FL (US)

(21) Appl. No.: 19/223,631

(22) Filed: May 30, 2025

Related U.S. Application Data
(60) Provisional application No. 63/658,925, filed on Jun. 12, 2024.

(51) Int. Cl. G06F 30/347

(52) U.S. Cl. CPC G06F 30/347

(57) ABSTRACT

A reconfiguration security fabric comprising a reconfigurable logic block (ReCLB) comprising a plurality of lookup tables (LUTs); one or more programmable input/output (PIO) routers comprising a plurality of multiplexers (MUXs) that determine routing of data to or from the ReCLB; a switch box that is configured to route a plurality of outputs from the plurality of LUTs to the one or more PIO routers; and a configuration bitstream that is communicatively coupled to the ReCLB, the one or more PIO routers, and the switch box, wherein functionality of the ReCLB, the one or more PIO routers, and the switch box is altered by shifting the configuration bitstream.

### CROSS REFERENCE TO RELATED APPLICATION

This application claims the priority of U.S. Provisional Application No. 63/658,925, entitled “RECONFIGURABLE SECURITY FABRIC FOR SECURING DIGITAL CIRCUIT DESIGNS,” filed on Jun. 12, 2024, the disclosure of which is hereby incorporated by reference in its entirety.

### TECHNICAL FIELD

Various embodiments of the present disclosure relate to digital circuit design security, and more particularly to protecting hardware intellectual property by inserting reconfigurable security fabric into digital circuit designs.

### BACKGROUND

Due to globalized distributed manufacturing in the semiconductor industry, concerns may arise about the trustworthiness and safeguarding of electronic designs. For example, under a zero-trust model, hardware intellectual property (IP) may be exposed to threats, such as piracy, counterfeiting, and reverse engineering. Third parties may exploit vulnerabilities in an untrusted supply chain by introducing malicious modifications or producing counterfeit chips.

Protecting electronic design IP blocks may be crucial in mitigating confidentiality and integrity risks. Applicant has identified many technical challenges and difficulties associated with providing a comprehensive and holistic solution that incorporates effective countermeasures for securing digital circuit designs.

### BRIEF SUMMARY

Various embodiments described herein relate to methods, apparatus, systems, computing devices, computing entities, and/or the like for protecting hardware intellectual property.

According to some embodiments, the method comprises inserting, by one or more processors, one or more reconfiguration security fabric (RSF) blocks into a digital circuit design, wherein (i) a RSF block of the one or more RSF blocks comprises a reconfigurable logic block (ReCLB), one or more programmable input/output (PIO) routers, and a switch box, and (ii) the ReCLB, the one or more PIO routers, and the switch box are programmable by a configuration bitstream; generating, by the one or more processors, a logical design based on the digital circuit design and the one or more RSF blocks; generating, by the one or more processors, a physical design based on the logical design; and initiating, by the one or more processors, a performance of one or more post-layout tasks corresponding to the physical design.

In some embodiments, inserting the one or more RSF blocks into the digital circuit design comprises inserting the one or more RSF blocks into a location within a combinational logic or sequential logic network. In some embodiments, generating the logical design comprises defining one or more design specifications; generating a register transfer level (RTL) behavioral description; synthesizing and performing a scan insertion; performing functional or formal verification; and performing static timing analysis. In some embodiments, generating the physical design comprises transforming the logical design into a physical layout. In some embodiments, generating the physical design comprises one or more of floor planning, placement and routing, design rule check, or creating a graphic design system file format for fabrication. In some embodiments, the one or more post-layout tasks comprises one or more of fabrication, packaging, or testing of a physical device. In some embodiments, the one or more RSF blocks comprise runtime reconfigurability that allows selection of one or more functions that limit rareness and signal probability determination of nodes.

According to some embodiments, a reconfiguration security fabric comprises a ReCLB comprising a plurality of lookup tables (LUTs); one or more PIO routers comprising a plurality of multiplexers (MUXs) that determine routing of data to or from the ReCLB; a switch box that is configured to route a plurality of outputs from the plurality of LUTs to the one or more PIO routers; and a configuration bitstream that is communicatively coupled to the ReCLB, the one or more PIO routers, and the switch box, wherein functionality of the ReCLB, the one or more PIO routers, and the switch box is altered by shifting the configuration bitstream.

In some embodiments, a MUX of the plurality of MUXs is configured to select a signal from serial input data based on the configuration bitstream; and route the signal to the ReCLB. In some embodiments, the configuration bitstream comprises a daisy-chained shift register with a serial bit input and a serial bit output. In some embodiments, the configuration bitstream is configured to provide (i) a combinational mode that generates a functional output based on combinational logic, or (ii) a sequential mode that generates scan outputs corresponding to output data provided to a data flip flop for sequential logic or scan/test mode operation. In some embodiments, a PIO router of the one or more PIO routers is configured to route output signals of the RSF. In some embodiments, the RSF further comprises a physical unclonable function (PUF), wherein the RSF is configured in a memory-based PUF that is configured to generate a PUF signature. In some embodiments, the RSF further comprises a physical unclonable function (PUF), wherein the RSF is configured in an RSF-based side-channel protection system, wherein the RSF-based side-channel protection system comprises an RSF-based universal noise generator (UNG) and an RSF-based PUF. In some embodiments, the RSF is configured in an RSF-based fault attack protection system, wherein the RSF-based fault attack protection system comprises a plurality of RSF-based structural variants and a majority voting function.

According to some embodiments, an RSF-based scan architecture comprises a combinational logic block; a scan chain comprising a plurality of scan flip flops that is coupled to the combinational logic block; and one or more RSFs that are inserted in the scan chain, wherein a RSF of the one or more RSFs is configured to (i) receive a first output from a first scan flip flop of the plurality of scan flip flops, (ii) generate a second output based on the first output, and (iii) provide the second output to a second scan flip flop of the plurality of scan flip flops that is subsequent to the first scan flip flop.

In some embodiments, the RSF comprises a configurable LUT that is configured to implement a bijective function, and the RSF is further configured to generate the second output by performing the bijective function on the first output; and provide the second output to the second scan flip flop of the plurality of scan flip flops. In some embodiments, the RSF is configured to reorder one or more scan flip flops of the plurality of scan flip flops based on one or more of (i) proximity to primary inputs or outputs, (ii) transition probabilities, or (iii) impact on power consumption. In some embodiments, the one or more RSFs are configured to insert a watermark associated with authenticating hardware. In some embodiments, the watermark comprises at least one of (i) selectively redacting one or more combinational logic gates of the combinational logic block, (ii) replacing one or more scan flip flops with a sequential RSF, (iii) inserting a dummy sequential RSF into the scan chain, or (iv) inserting a dummy combinational RSF into the combinational logic block.

### BRIEF DESCRIPTION OF THE DRAWINGS

Embodiments incorporating teachings of the present disclosure are shown and described with respect to the figures presented herein.

FIG. 1 is an example overview of an architecture in accordance with some embodiments of the present disclosure.

FIG. 2 provides an example computing entity in accordance with some embodiments of the present disclosure.

FIG. 3 provides an example client computing entity in accordance with some embodiments of the present disclosure.

FIG. 4 is an example digital integrated circuit (IC) in accordance with some embodiments of the present disclosure.

FIG. 5 is a block diagram of an example reconfiguration security fabric (RSF) block in accordance with some embodiments of the present disclosure.

FIG. 6 is a block diagram of an example 2×1 RSF block in accordance with some embodiments of the present disclosure.

FIG. 7 depicts a block diagram of an example reconfigurable logic block ReCLB in accordance with some embodiments of the present disclosure.

FIG. 8 is an operational example of a 2×1 LUT in accordance with some embodiments of the present disclosure.

FIG. 9 is a block diagram of an example ReCLB in accordance with some embodiments of the present disclosure.

FIG. 10 and FIG. 11 are block diagrams of example switch boxes in accordance with some embodiments of the present disclosure.

FIG. 12 and FIG. 13 are block diagrams of example PIO routers in accordance with some embodiments of the present disclosure.

FIG. 14 is a block diagram of an example scan architecture.

FIG. 15A depicts an example flip flop.

FIG. 15B depicts an example flip flop that is driven by MUXed logic.

FIG. 15C is an example RSF-based flip flop in accordance with some embodiments of the present disclosure.

FIGS. 16 and 17 are example RSF-based scan architectures in accordance with some embodiments of the present disclosure.

FIG. 18 depict example rearrangements of a scan chain in accordance with some embodiments of the present disclosure.

FIG. 19A is a block diagram of an example RSF architecture for increasing observability in accordance with some embodiments of the present disclosure.

FIG. 19B is a block diagram of an example RSF architecture for increasing controllability in accordance with some embodiments of the present disclosure.

FIG. 20A through 20C are block diagrams of example RSF architectures for improving testability in accordance with some embodiments of the present disclosure.

FIG. 21 is a block diagram of an example DFT scan-chain in accordance with some embodiments of the present disclosure.

FIG. 22 is a block diagram of an example RSF-based hardware watermark generation architecture in accordance with some embodiments of the present disclosure.

FIG. 23A depicts an example unit primitive of a MeLPUF cell.

FIG. 23B depicts an example integration of an MeLPUF cell into a combinational part of a circuit in accordance with some embodiments of the present disclosure.

FIG. 23C depicts an extraction of a MeLPUF signature from a combinational circuit in accordance with some embodiments of the present disclosure.

FIG. 24A depicts a representation of a RSF primitive corresponding to a 1-bit PUF in accordance with some embodiments of the present disclosure.

FIG. 24B depicts a 2-bit PUF signature using a 2×2 RSF block in accordance with some embodiments of the present disclosure.

FIG. 25 is a block diagram of an example RSF-based side channel protection architecture in accordance with some embodiments of the present disclosure.

FIG. 26 is a block diagram of an example RSF-based universal noise generator (UNG) in accordance with some embodiments of the present disclosure.

FIG. 27A through FIG. 27D depict example structural variants for a XOR function.

FIG. 28A through FIG. 28D depict example structural variants of a full adder circuit.

FIG. 29 and FIG. 30 are block diagrams of example RSF-based fault attack protection architectures in accordance with some embodiments of the present disclosure.

FIG. 31 depicts a majority voting logic in accordance with some embodiments of the present disclosure.

FIG. 32 presents a flowchart of an example process for integrating RSF-based security features into stages of an IC design flow according to some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

The present disclosure provides a programmable lookup table (LUT)-based security framework that may contribute to and improve existing protection strategies for securing hardware intellectual property (IP) against a wide range of attacks under a zero-trust model. The adoption of the zero-trust model has caused significant concerns for the confidentiality and integrity of a design in the presence of untrusted entities. Existing methods for protecting digital circuit designs may comprise strategies, such as inserting watermarks and physical unclonable functions (PUFs) for authentication purposes, alongside the deployment of secure scan chains for testing purposes in untrusted facilities. While the existing methods bolster security to some extent, vulnerabilities persist, particularly in the form of side-channel and fault attacks. Side-channel attacks may exploit unintentional information leakage, while fault attacks may manipulate circuit behavior to compromise security.

According to various embodiments of the present disclosure, a reconfigurable security fabric (RSF) framework provides one or more security functionalities for countering security threats and fortifying digital circuit designs against malicious exploits. The incorporation of RSFs in digital circuit designs may solve various aspects of hardware security, offering a range of features that enhance robustness and resilience. In some embodiments, a RSF framework comprises a range of features, such as robust scan protection mechanisms, watermark generation capabilities, secure PUF signature generation, effective side channel protection measures, redundancy-based fault attack protection mechanisms, or enhancements to testability while reducing test power consumption.

In some embodiments, RSFs are used to secure digital circuit designs against scan chain attacks, offering dynamic reconfiguration or reordering of scan chains. In some embodiments, RSFs are used to facilitate the generation of hardware watermarks that comprise unique identifiers embedded in a digital circuit design for verifying authenticity. RSFs may incorporate the generation of unique PUF signatures by leveraging metastability of a cross-coupled inverter pair, which may be effective in chip authentication. In some embodiments, an RSF-based fault attack-resistant architecture offers duplication of critical functions with configurability through RSF. In some other embodiments, an RSF-based side channel attack-resistant architecture comprises a universal noise generator (UNG) for generating random noise to protect against differential power analysis (DPA) attacks. In some embodiments, an incorporation of one or more RSFs in a digital circuit design comprises a comprehensive solution that is an improvement over conventional security measures that addresses common security threats while providing authentication standards, such as generating hardware watermarks and PUF signatures, and provides improvements in test power efficiency and testability of digital circuit designs.

As disclosed herewith, a RSF may be inserted into a digital circuit (e.g., IC) design at various stages of a digital circuit design flow to protect hardware IP of the digital circuit design from adversaries. In some embodiments, a RSF comprises runtime reconfigurability that allows the selection of various functions by applying corresponding bitstream values, which significantly enhances security by limiting rareness and signal probability determination of nodes which may improve protection against hardware Trojan attacks. According to various embodiments, an RSF-based framework provides comprehensive security features for upholding confidentiality, integrity, and availability properties of digital circuit designs. In some embodiments, a secure RSF-based design-for-testability (DFT) architecture for protecting scan chains comprises (i) one or more configurable LUTs configured to implement one or more bijective functions (e.g., XOR/XNOR) that transform original input test patterns and (ii) a post-processing stage that is applied on transformed output test patterns to retrieve and verify the original input test patterns.

In some embodiments, RSF-based systems and methods are provided for generating unique watermarks for hardware IP authentication that are difficult to detect, modify, forge or tamper with, or remove. In some embodiments, scalable distributed memory RSF-based PUF systems and methods are provided for generating high-quality PUF signatures with high degree of robustness, uniqueness, and randomness. In some embodiments, optimized RSF-based scan-chain reordering systems and methods are provided for test power improvement by minimizing switching activity and power consumption during testing. In some embodiments, RSF-based systems and methods are provided for improving testability by increasing the controllability and observability of internal nets in a digital circuit design. In some embodiments, RSF-based side-channel protection systems and methods using RSF-based UNG circuits and RSF-based PUFs are provided for preventing DPA-based attacks on protected functions in cryptographic systems. In some embodiments, RSF-based fault attack protection systems and methods that use redundant structural variants and a majority voting algorithm are provided for generating corrected outputs from critical function blocks. In some embodiments, RSF-based systems and methods are seamlessly integrated with electronic design automation (EDA) tool flow for application-specific integrated circuit (ASIC) and field-programmable gate array (FPGA) design methodologies.

### Example Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established, or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid-state card (SSC), solid-state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FcRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

### Example System Architecture

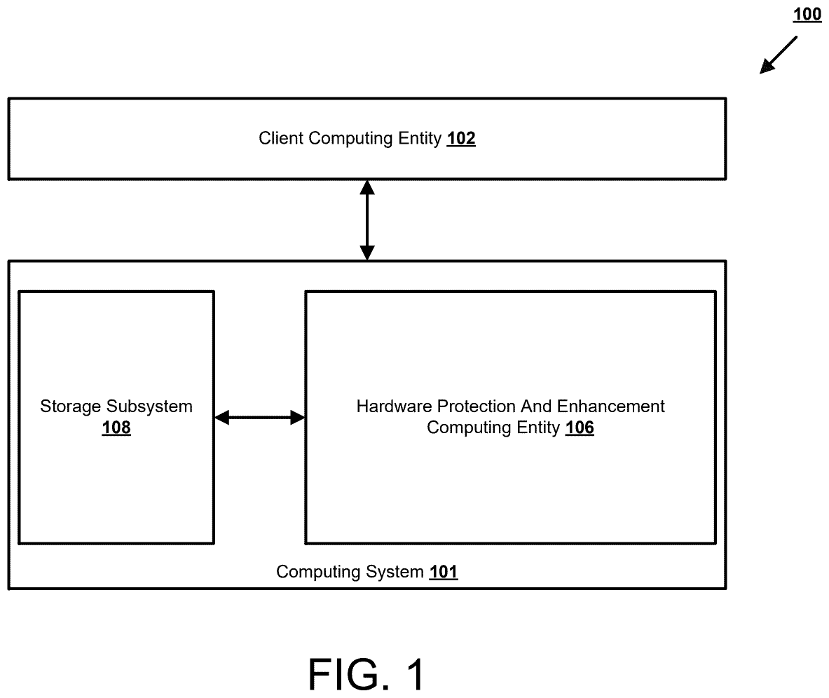

FIG. 1 provides an example overview of an architecture 100 in accordance with some embodiments of the present disclosure. The architecture 100 includes a computing system 101 configured to receive digital circuit design protection and enhancement requests from client computing entity 102, process the digital circuit design protection and enhancement requests to perform one or more digital circuit design protection and enhancement actions corresponding to the digital circuit design protection and enhancement requests, and provide results or output from the performance of the one or more digital circuit design protection and enhancement actions to the client computing entity 102.

In some embodiments, computing system 101 may communicate with at least one of the client computing entity 102 using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software, and/or firmware required to implement it (such as, e.g., network routers, and/or the like).

The computing system 101 may include a hardware protection and enhancement computing entity 106 and a storage subsystem 108. The hardware protection and enhancement computing entity 106 may be configured to receive digital circuit design protection and enhancement requests from client computing entity 102, process the digital circuit design protection and enhancement requests to perform one or more digital circuit design protection and enhancement actions corresponding to the digital circuit design protection and enhancement requests, and provide results or output from the performance of the one or more digital circuit design protection and enhancement actions to the client computing entity 102.

The storage subsystem 108 may be configured to store input data used by the hardware protection and enhancement computing entity 106 to perform hardware IP protection and security functions. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including, but not limited to, hard disks, ROM, PROM, EPROM, EEPROM, flash memory, MMCs, SD memory cards, Memory Sticks, CBRAM, PRAM, FRAM, NVRAM, MRAM, RRAM, SONOS, FJG RAM, Millipede memory, racetrack memory, and/or the like.

### Example Data Analysis Computing Entity

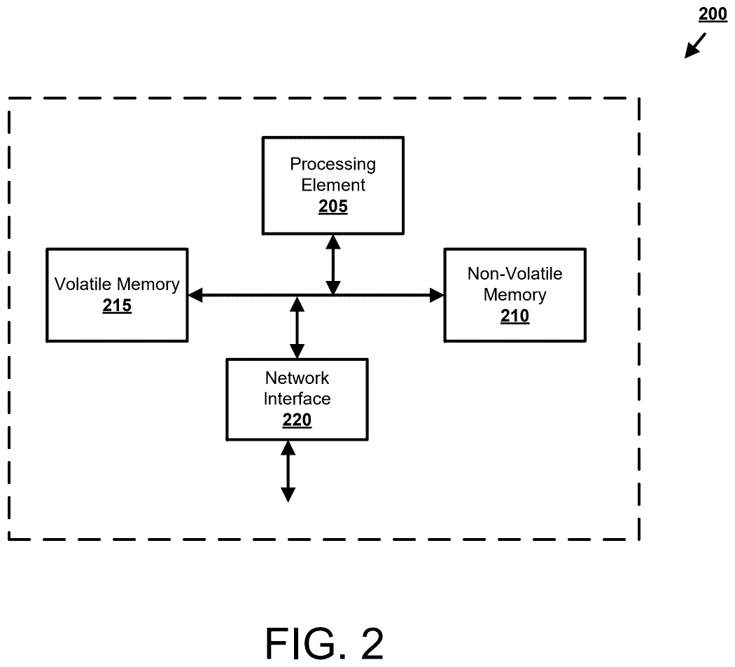

FIG. 2 provides an example computing entity 200 in accordance with some embodiments of the present disclosure. The computing entity 200 is an example of the hardware protection and enhancement computing entity 106. In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

As indicated, in one embodiment, the computing entity 200 may also include one or more network interfaces 220 for communicating with various computing entities, such as by communicating data, content, information, and/or similar terms used herein interchangeably that may be transmitted, received, operated on, processed, displayed, stored, and/or the like.

As shown in FIG. 2, in one embodiment, the computing entity 200 may include, or be in communication with, one or more processing elements 205 (also referred to as processors, processing circuitry, and/or similar terms used herein interchangeably) that communicate with other elements within the computing entity 200 via a bus, for example. As will be understood, the processing elements 205 may be embodied in a number of different ways.

For example, the processing elements 205 may be embodied as one or more complex programmable logic devices (CPLDs), microprocessors, multi-core processors, coprocessing entities, application-specific instruction-set processors (ASIPs), microcontrollers, and/or controllers. Further, the processing elements 205 may be embodied as one or more other processing devices or circuitry. The term circuitry may refer to an entirely hardware embodiment or a combination of hardware and computer program products. Thus, the processing elements 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing elements 205 may be configured for a particular use or configured to execute instructions stored in volatile or non-volatile media or otherwise accessible to the processing elements 205. As such, whether configured by hardware or computer program products, or by a combination thereof, the processing elements 205 may be capable of performing steps or operations according to embodiments of the present disclosure when configured accordingly.

In one embodiment, the computing entity 200 may further include, or be in communication with, non-volatile media (also referred to as non-volatile storage, memory, memory storage, memory circuitry, and/or similar terms used herein interchangeably). In one embodiment, the non-volatile storage or memory may include one or more non-volatile storage or memory media 210, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In one embodiment, the computing entity 200 may further include, or be in communication with, volatile media (also referred to as volatile storage, memory, memory storage, memory circuitry, and/or similar terms used herein interchangeably). In one embodiment, the volatile storage or memory may also include one or more volatile storage or memory media 215, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing elements 205. Thus, the databases, database instances, database management systems, data, applications, programs, program modules, scripts, source code, object code, byte code, compiled code, interpreted code, machine code, executable instructions, and/or the like may be used to control certain aspects of the operation of the computing entity 200 with the assistance of the processing elements 205 and operating system.

As indicated, in one embodiment, the computing entity 200 may also include one or more network interfaces 220 for communicating with various computing entities, such as by communicating data, content, information, and/or similar terms used herein interchangeably that may be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 200 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing entity 200 may include, or be in communication with, one or more input elements, such as a keyboard input, a mouse input, a touch screen/display input, motion input, movement input, audio input, pointing device input, joystick input, keypad input, and/or the like. The computing entity 200 may also include, or be in communication with, one or more output elements (not shown), such as audio output, video output, screen/display output, motion output, movement output, and/or the like.

### Example Client Computing Entity

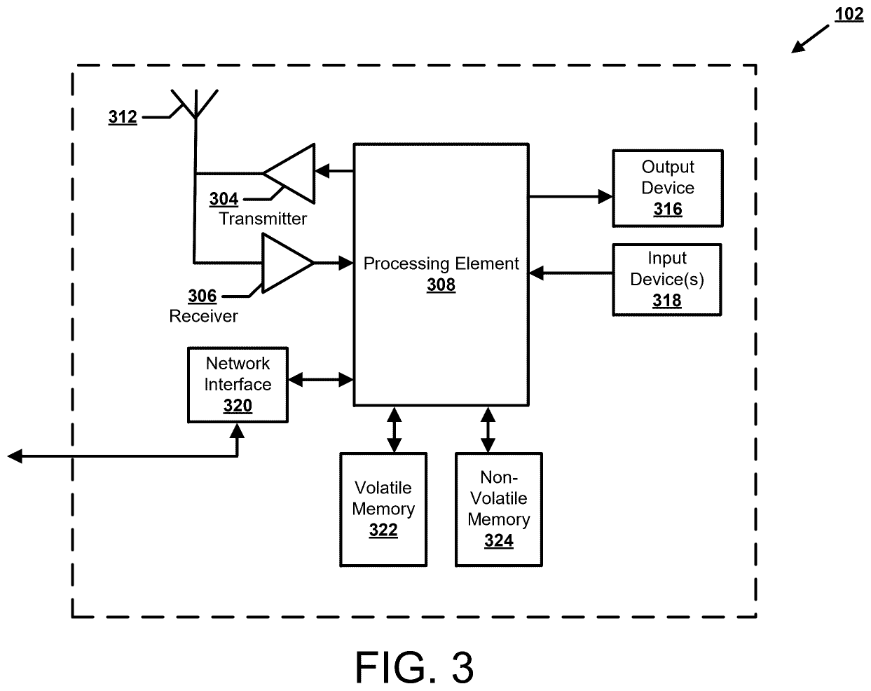

FIG. 3 provides an example client computing entity 102 in accordance with some embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entity 102 may be operated by various parties. As shown in FIG. 3, the client computing entity 102 may include an antenna 312, a transmitter 304 (e.g., radio), a receiver 306 (e.g., radio), and a processing element 308 (e.g., CPLDs, microprocessors, multi-core processors, coprocessing entities, ASIPs, microcontrollers, and/or controllers) that provides signals to and receives signals from the transmitter 304 and receiver 306, correspondingly.

The signals provided to and received from the transmitter 304 and the receiver 306, correspondingly, may include signaling information/data in accordance with air interface standards of applicable wireless systems. In this regard, the client computing entity 102 may be capable of operating with one or more air interface standards, communication protocols, modulation types, and access types. More particularly, the client computing entity 102 may operate in accordance with any of a number of wireless communication standards and protocols, such as those described above with regard to the computing entity 200. In a particular embodiment, the client computing entity 102 may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the client computing entity 102 may operate in accordance with multiple wired communication standards and protocols, such as those described above with regard to the computing entity 200 via a network interface 320.

Via these communication standards and protocols, the client computing entity 102 may communicate with various other entities using concepts such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The client computing entity 102 may also download changes, add-ons, and updates, for instance, to its firmware, software (e.g., including executable instructions, applications, program modules), and operating system.

According to one embodiment, the client computing entity 102 may include location determining aspects, devices, modules, functionalities, and/or similar words used herein interchangeably. For example, the client computing entity 102 may include outdoor positioning aspects, such as a location module adapted to acquire, for example, latitude, longitude, altitude, geocode, course, direction, heading, speed, universal time (UTC), date, and/or various other information/data. In one embodiment, the location module may acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data may be collected using a variety of coordinate systems, such as the DecimalDegrees (DD); Degrees, Minutes, Seconds (DMS); Universal Transverse Mercator (UTM); Universal Polar Stereographic (UPS) coordinate systems; and/or the like. Alternatively, the location information/data may be determined by triangulating a position of client computing entity 102 in connection with a variety of other systems, including cellular towers, Wi-Fi access points, and/or the like. Similarly, the client computing entity 102 may include indoor positioning aspects, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops), and/or the like. For instance, such technologies may include the iBeacons, Gimbal proximity beacons, Bluetooth Low Energy (BLE) transmitters, NFC transmitters, and/or the like. These indoor positioning aspects may be used in a variety of settings to determine the location of someone or something to within inches or centimeters.

The client computing entity 102 may also comprise a user interface (that may include an output device 316 (e.g., display, speaker, tactile instrument, etc.) coupled to a processing element 308) and/or a user input interface (coupled to a processing element 308). For example, the user interface may be a user application, browser, user interface, and/or similar words used herein interchangeably executing on and/or accessible via the client computing entity 102 to interact with and/or cause display of information/data from the computing entity 200, as described herein. The user input interface may comprise any of a plurality of input devices 318 (or interfaces) allowing the client computing entity 102 to receive code and/or data, such as a keypad (hard or soft), a touch display, voice/speech or motion interfaces, or other input device. In some embodiments including a keypad, the keypad may include (or cause display of) the conventional numeric (0-9) and related keys (#, *), and other keys used for operating the client computing entity 102 and may include a full set of alphabetic keys or set of keys that may be activated to provide a full set of alphanumeric keys. In addition to providing input, the user input interface may be used, for example, to activate or deactivate certain functions, such as screen savers and/or sleep modes.

The client computing entity 102 may also include volatile storage or memory 322 and/or non-volatile storage or memory 324, which may be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory may store databases, database instances, database management systems, data, applications, programs, program modules, scripts, source code, object code, byte code, compiled code, interpreted code, machine code, executable instructions, and/or the like to implement the functions of the client computing entity 102. As indicated, this may include a user application that is resident on the client computing entity 102 or accessible through a browser or other user interface for communicating with the computing entity 200 and/or various other computing entities.

In another embodiment, the client computing entity 102 may include one or more components or functionality that are the same or similar to those of the computing entity 200, as described in greater detail above. As will be recognized, these architectures and descriptions are provided for exemplary purposes only and are not limited to the various embodiments.

In various embodiments, the client computing entity 102 may be embodied as an artificial intelligence (AI) computing entity. Accordingly, the client computing entity 102 may be configured to provide and/or receive information/data from a user via an input/output mechanism, such as a display, a camera, a speaker, a voice-activated input, and/or the like. In certain embodiments, an Al computing entity may comprise one or more predefined and executable program algorithms stored within an onboard memory storage module, and/or accessible over a network. In various embodiments, the AI computing entity may be configured to retrieve and/or execute one or more of the predefined program algorithms upon the occurrence of a predefined trigger event.

### Example Reconfigurable Security Fabric (RSF)

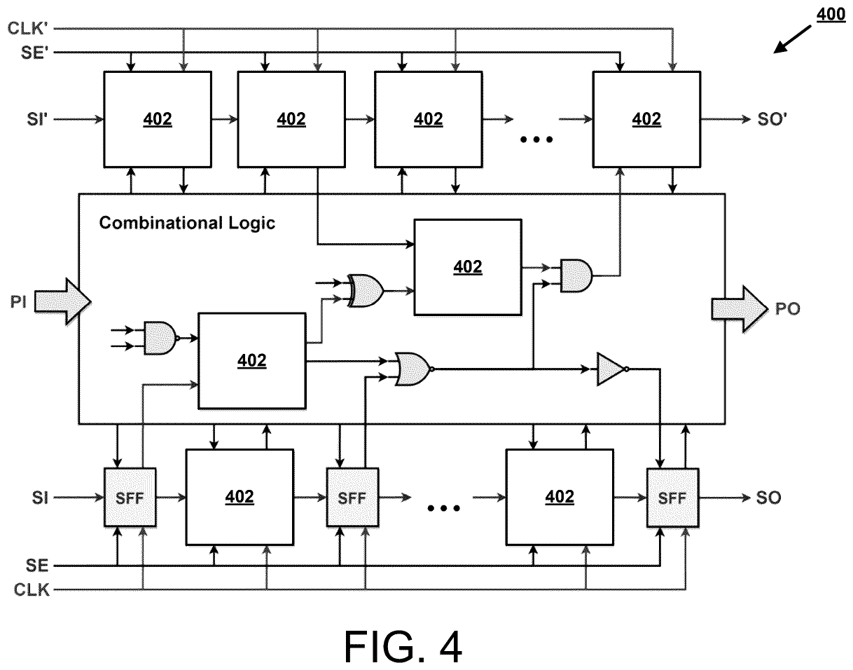

FIG. 4 is an example digital IC 400 in accordance with some embodiments of the present disclosure. As depicted in FIG. 4, a plurality of RSF blocks 402 is integrated into a combinational logic and/or sequential logic (e.g., scan chains) network of the digital IC 400. The plurality of RSF blocks 402 may be daisy chained to form a shift register as part of an existing scan architecture. In some embodiments, the plurality of RSF blocks 402 may either replace existing critical Boolean logic gates or be implemented as dummy logic functions without modifying a true or intended functionality of the design of digital IC 400. RSF blocks 402 may also be inserted into the scan chain of the digital IC 400 to replace existing data/scan flip flops or may be added as dummy scan elements. For example, RSF blocks 402 that are inserted into digital IC 400 may be connected to the original scan chain or connected to each other to form a new scan chain.

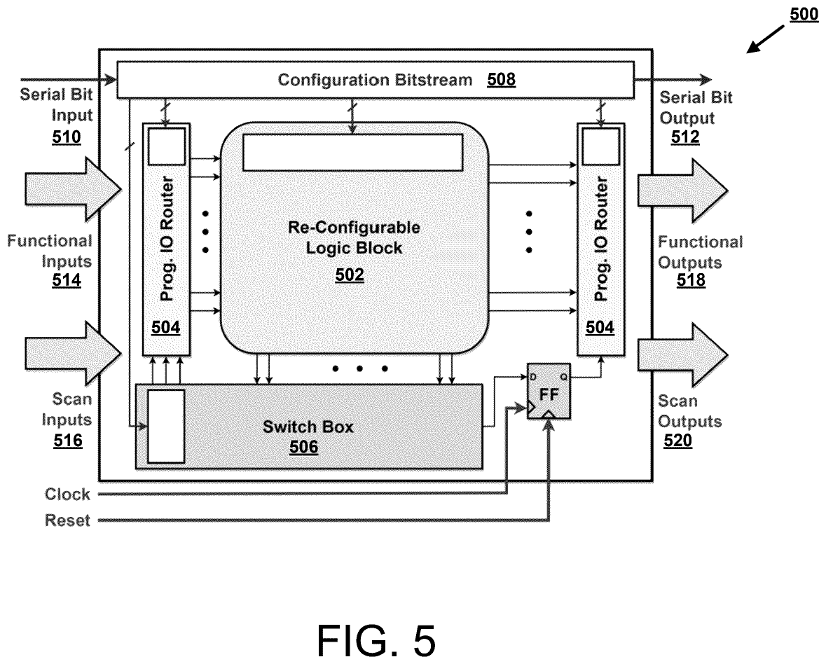

FIG. 5 is a block diagram of an example RSF block 500 in accordance with some embodiments of the present disclosure. The RSF block 500 is an example of the RSF blocks 402 of FIG. 4. The RSF block 500 comprises a reconfigurable logic block (ReCLB) 502, a plurality of programmable input/output (PIO) routers 504, and a switch box 506. Each of the ReCLB 502, PIO routers 504, and switch box 506 is programmed by a configuration bitstream.

In some embodiments, the ReCLB 502 may comprise a plurality of LUTs. LUTs may comprise components that serve as building blocks in digital circuit designs, such as of field-programmable gate arrays (FPGAs) and application-specific integrated circuits (ASICs). As such, LUTs may play a critical role in implementing combinational logic functions and comprise versatile elements that may contribute to the flexibility and programmability of digital circuits. In some embodiments, each LUT of the ReCLB 502 is configured to achieve an intended functionality (of a digital design) via a bitstream.

In some embodiments, the switch box 506 is configured to route outputs from LUTs of the ReCLB 502 to PIO routers 504. The PIO routers 504 may be configured as a collection of multiplexers (MUX) that determine a routing configuration of the PIO routers 504. In some embodiments, a MUX of a PIO router of the PIO routers 504 is configured to select particular signals from serial input data received by the RSF block 500 to the LUTs of the ReCLB 502 based on control inputs that are configured by values from a configuration bitstream 508 and connect/route respective signals to the ReCLB 502.

In some embodiments, the configuration bitstream 508 comprises a daisy-chained shift register with serial bit input 510 and serial bit output 512 ports. Serial bitstream loading in the RSF block 500 may create high degrees of functional and structural randomness (that is desirable for security) as shifting a bitstream by at least one bit alters the functionality (and hence the Boolean logic implemented) of each LUT (e.g., ReCLB 502) and other programmable elements (e.g., PIO routers 504 and switch box 506) connected to the shift register. In addition to design time (or static) reconfiguration, shifting the bitstream at runtime allows dynamic reconfiguration of an intended functionality (of a digital design) and enables implementation of one or more security/enhancement features using a same RSF block. Inputs to the RSF block 500 may comprise functional inputs 514 and scan inputs 516. According to various embodiments of the present disclosure, the RSF block 500 is configured to operate in two modes: (i) combinational mode, which produces functional outputs 518 for a normal mode of operation for pure combinational logic, and (ii) sequential mode, which routes output values to data flip flops as per the designs for normal sequential and scan/test mode operations, and generates scan outputs 520. The mode of operation may also be configured using the bitstream.

### Reconfigurable Logic Block (ReCLB)

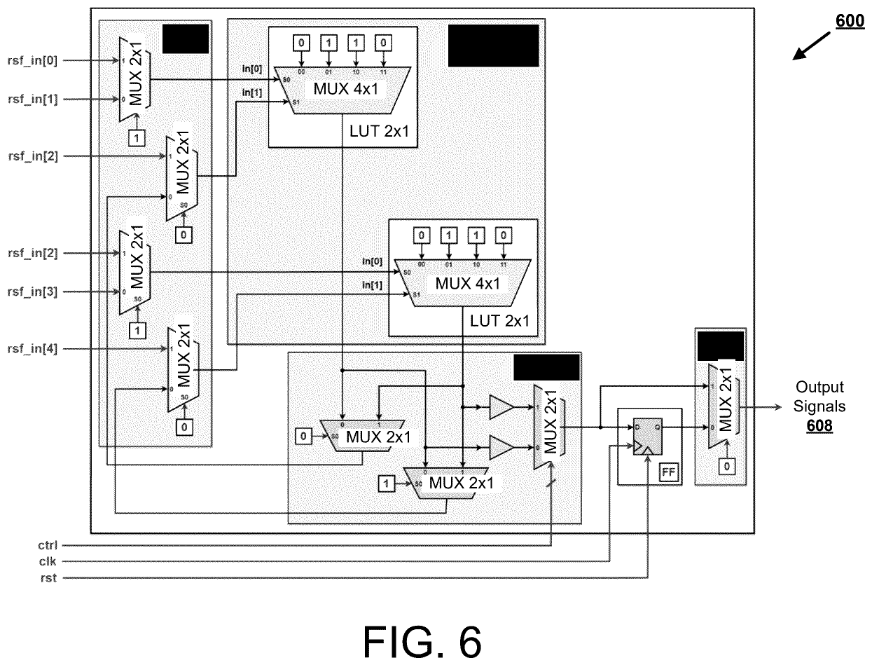

FIG. 6 is a block diagram of an example 2×1 RSF block 600 in accordance with some embodiments of the present disclosure. As depicted in FIG. 6, the 2×1 RSF block 600 comprises a ReCLB 602. A ReCLB 602 may comprise a building block of a RSF framework that offers configurability and versatility to achieve a wide range of logic functions. That is, unlike traditional circuits, a ReCLB 602 may provide programmability to perform intended functions. In some embodiments, a ReCLB 602 comprises one or more configurable N×1 LUTs, where N represents the number of inputs to the LUT.

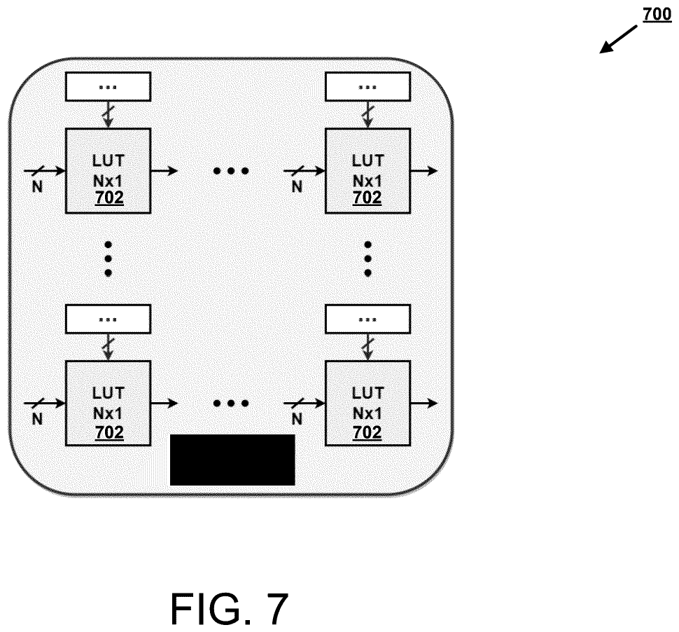

FIG. 7 depicts a block diagram of an example ReCLB 700 in accordance with some embodiments of the present disclosure. The ReCLB 700 is an example of the ReCLB 602 in FIG. 6 comprising one or more configurable N×1 LUTs 702. A total number of possible logic functions that may be implemented for an N×1 LUT may be expressed as 2²^{^{N}}. The value of N may be determined based on the complexity of the intended logic functions. For example, if a logic function uses four input variables, an N×1 LUT with N=4 may be used to accommodate a desired number of input combinations. A ReCLB 700 may comprise larger LUTs with respective configurations. In some example embodiments, a ReCLB 700 comprises a plurality 2x 1 LUTs that may be configured with a bitstream of size 4 and support 16 possible functions.

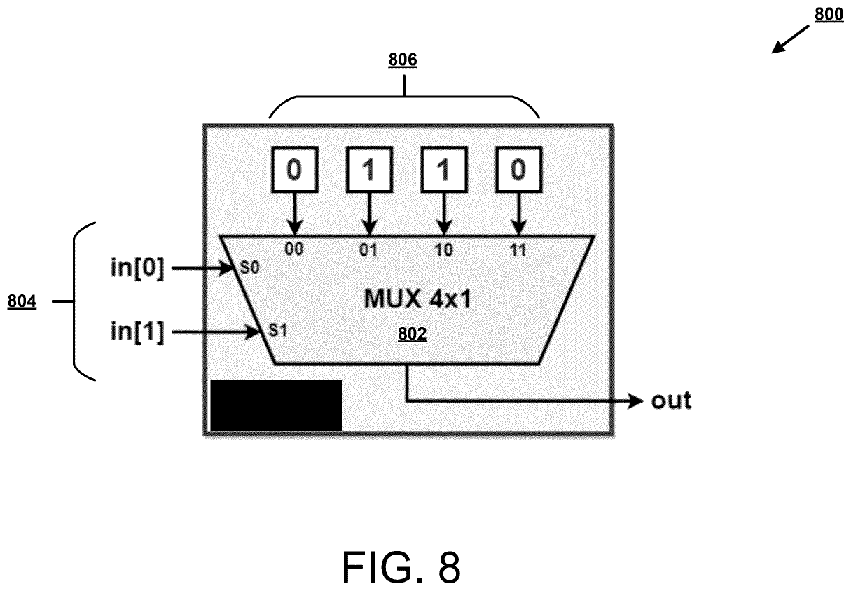

FIG. 8 is an operational example of a 2×1 LUT 800 in accordance with some embodiments of the present disclosure. The 2×1 LUT 800 comprises a 4×1 multiplexer (MUX) 802 that is configured with two select lines 804, in [0] and in [1], configured as inputs and the MUX inputs are coupled to bitstream values 806.

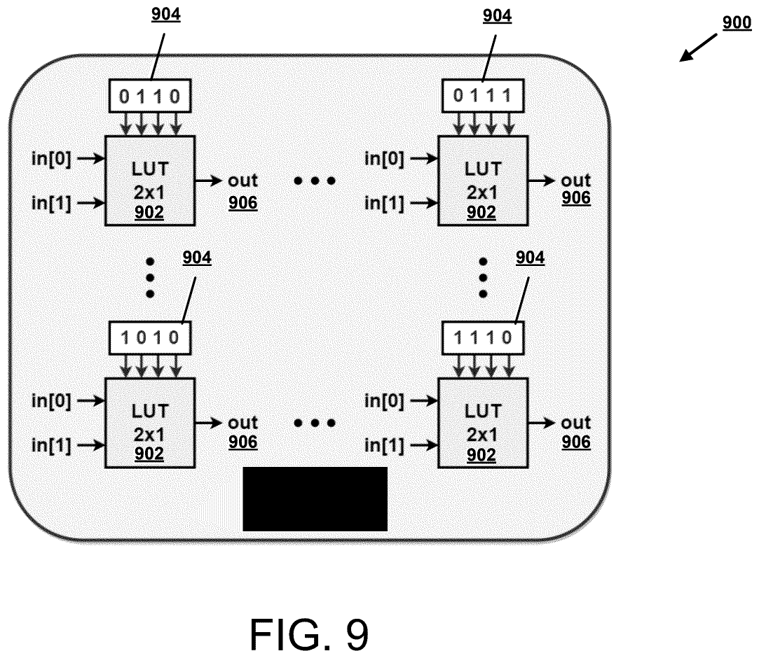

FIG. 9 is a block diagram of an example ReCLB 900 in accordance with some embodiments of the present disclosure. The ReCLB 900 comprises a network of a plurality of 2×1 LUTs 902 that may be configured with varying functions using respective bitstream values 904 in multiple rows and columns. In some example embodiments, the plurality of 2×1 LUTs 902 in ReCLB 900 may be interconnected to a switch box (e.g., switch box 506) for routing output 906 from the 2×1 LUTs 902 through PIO routers (e.g., PIO routers 504) and back to ReCLB 900 for an intended operation.

### Switch Box

Referring back to FIG. 6, the 2×1 RSF block 600 further comprises a switch box 604. The switch box 604 may be configured to direct outputs of individual LUTs within the ReCLB 602 to PIO routers 606 for providing a data flow of an intended operation. Once routed through the switch box 604 and PIO routers 606, the outputs may be directed back to the ReCLB 602. In some embodiments, the switch box 604 comprises a plurality of serially connected multiplexers (MUXes) of size N×1, where N may represent the number of LUTs present in the ReCLB 602. As such, the switch box 604 may efficiently manage the routing of outputs from individual LUTs of the ReCLB 602 to PIO routers 606. As further depicted in FIG. 6, N outputs from ReCLB 602 are routed via PIO routers 606 at the input side of the switch box 604. One more N×1 MUX with [log 2N] select lines are placed at the output side of the switch box 604, which may be driven by a control signal that governs the routing of buffered N input values from the ReCLB 602 to the PIO routers 606 for the respective operation. Hence, the switch box 604 may be represented as N×(N+1) where N may comprise the inputs from ReCLB 602 and (N+1) may comprise the number of N×1 MUXes.

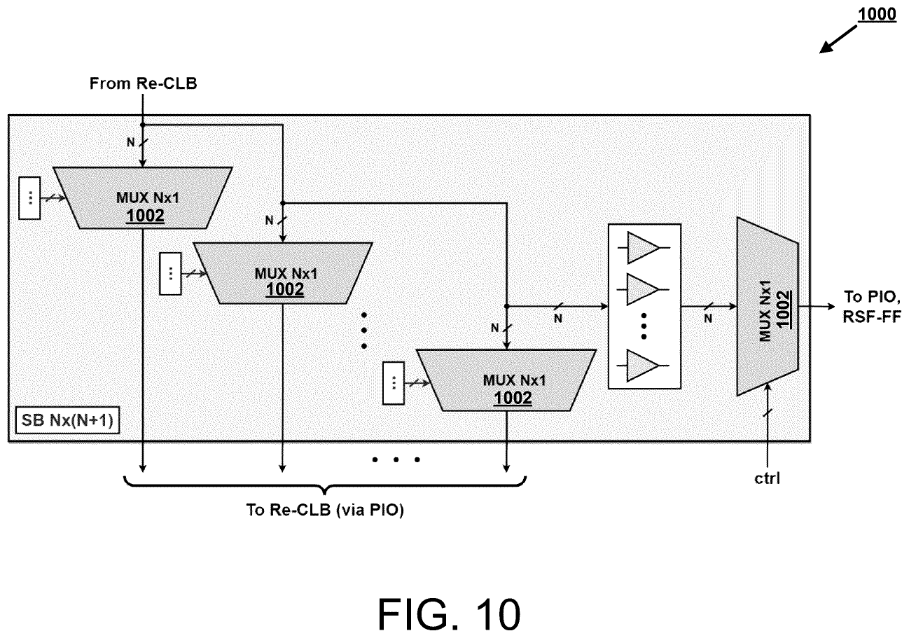

FIG. 10 is a block diagram of an example switch box 1000 in accordance with some embodiments of the present disclosure. The switch box 1000 comprises a plurality of N×1 MUXes 1002. The value of N may be configured to match a LUT configuration within a ReCLB that is coupled to the switch box 1000.

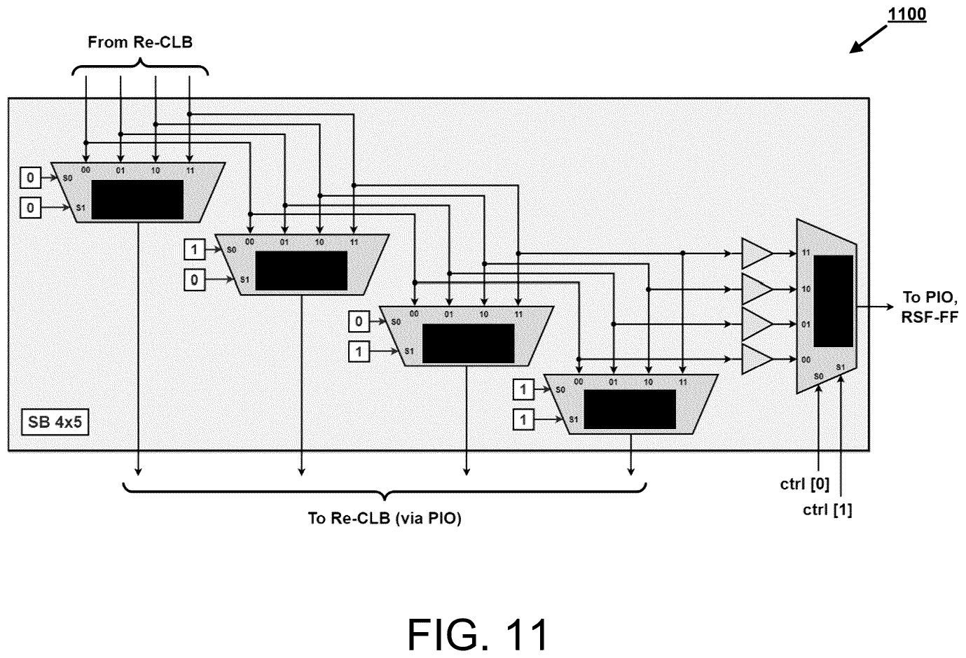

FIG. 11 is a block diagram of an example switch box 1100 in accordance with some embodiments of the present disclosure. The switch box 1100 is associated with a ReCLB that comprises four 2×1 LUTs, and as such comprises a plurality of 4×1 MUXes 1102 (4×5 switch box using 4×1 MUXes) to accommodate outputs from individual LUTs of a ReCLB and route signal values through PIO routers.

### Programmable Input/Output (PIO) Routers

Referring back to FIG. 6, the 2×1 RSF block 600 further comprises PIO routers 606, which comprise components of a RSF framework that facilitate routing of signals to or from the ReCLB 602. In some embodiments, an output side PIO router of the PIO routers 606 is configured to handle routing of output signals 608 of the RSF block 600. A PIO router (606) may be configured dynamically by using a bitstream for an intended operation. A PIO router (606) comprises one or more 2×1 MUXs with inputs routed from a switch box 604 along with scan inputs, while a select line of each MUX may be configured using bitstream values. A quantity of 2×1 MUXes in the PIO router (606) may be determined by a number of signals received from a switch box (604), which may depend on a number of LUTs in a ReCLB (602) coupled to the switch box (604).

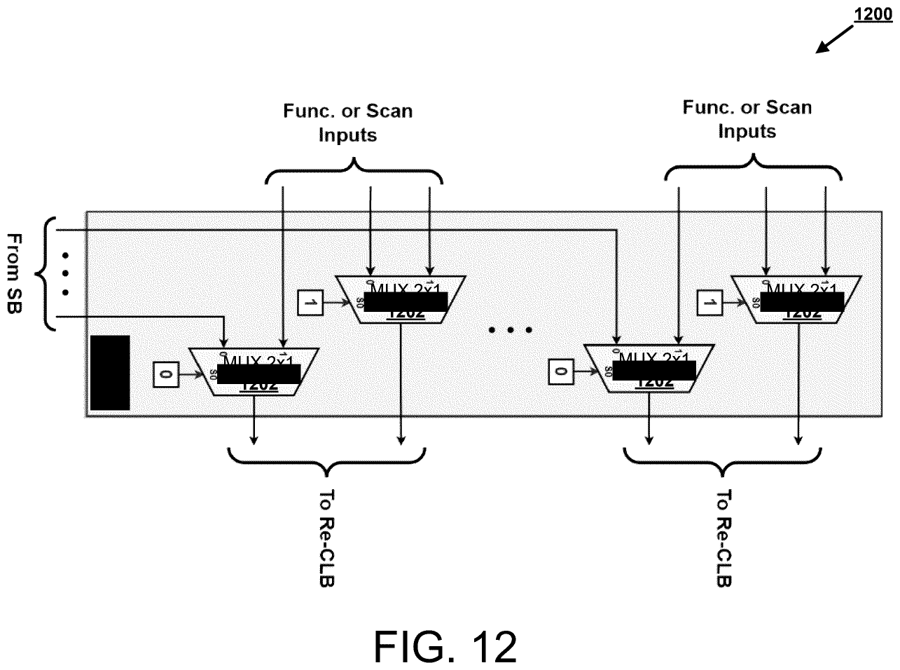

FIG. 12 is a block diagram of an example PIO router 1200 in accordance with some embodiments of the present disclosure. The PIO router 1200 comprises a plurality of 2×1 MUXes 1202 that route signals from a switch box to a ReCLB. In some example embodiments, the PIO router 1200 is configured at an input side of a RSF for routing functional/scan inputs and signals from a switch box to a ReCLB.

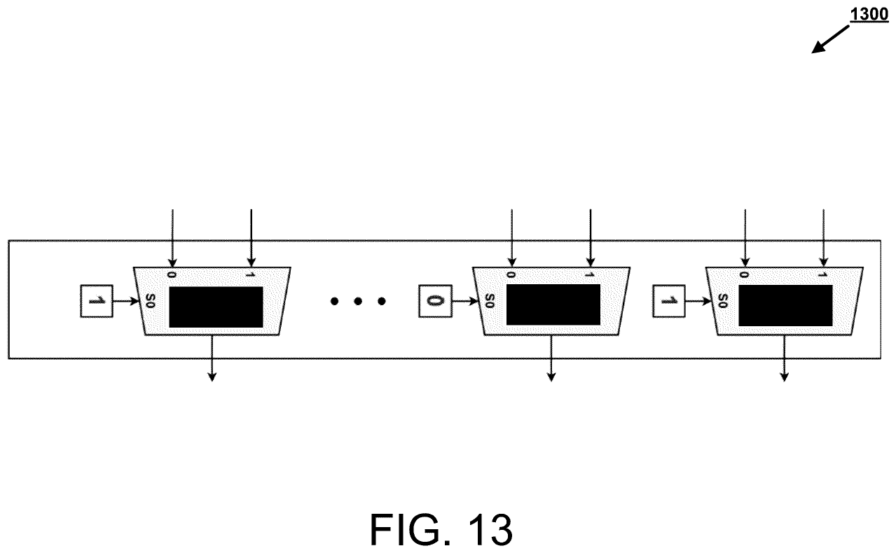

FIG. 13 is a block diagram of an example PIO router 1300 in accordance with some embodiments of the present disclosure. The PIO router 1300 comprises a plurality of 2×1 MUXes 1302. In some example embodiments, the PIO router 1300 is configured at an output side of a RSF (e.g., ReCLB and switch box) for routing output values generated by the RSF which may be coupled to one or more subsequent logic blocks (e.g., one or more flip flop) as per an original design.

### Benefits of LUT-Based Reconfigurable Security

Incorporating RSFs to protect scan chains may comprise leveraging the programmable and configurable nature of LUTs to introduce confusion, obfuscation, or dynamic reconfiguration. According to various embodiments of the present disclosure, a LUT-based RSF provides the following benefits:

### Dynamic Reconfiguration:

The reconfigurable nature of LUTs allows for contents of the LUTs to be changed dynamically. For example, a scan chain protection strategy may comprise periodically reconfiguring LUTs within a scan path, which may add a degree of challenge for an attacker to deduce actual functionality from the scan chain.
Confusion and Obfuscation:

Strategically configuring LUTs to generate protected outputs by using a bijective function may cause confusion for an attacker attempting to extract meaningful information from a scan chain. Protected outputs may be post-processed to obtain the actual values.

### Selective Activation/Deactivation:

LUTs may be selectively activated or deactivated based on certain conditions or triggers. Selective activation of LUTs may be controlled by secure mechanisms, allowing dynamic manipulation of scan chain behavior.

### Key-Based Configuration:

Secure configuration of LUTs based on keys may be implemented to control the behavior of the LUTs. For example, the use of key-based locking techniques may add an extra layer of protection to the scan chain.

### Combinational Loops in RSF Blocks

RSF blocks may comprise internal logic that is configured in a manner that creates combinational/timing loops between a ReCLB, a switch box, and an input side PIO router. If an output data flip flop is bypassed, the combinational loops may be handled to ensure that subsequent stages of an IC design flow are not impacted after RSF insertion.

Commercial EDA tools for synthesis and “place and route” (e.g., Design Compiler and IC Compiler from Synopsys, Genus and Innovus from Cadence, etc.) may support user-specified design constraints to disable combinational loops or handle the loops themselves using loop breaker cells. In some embodiments, a RSF framework generates design constraints for disabling combinational loops in a Synopsys Design Constraint (SDC) file format, which may be read into EDA tools, to ensure that combinational timing loops do not interfere with any stage of a digital circuit design flow.

### Brute-Force Complexity for RSF

For a given RSF block, let:
Number of LUT rows in ReCLB: n_{row}
Number of LUT columns in ReCLB: n_{col}
Number of LUTs in ReCLB: n_{LUT}=n_{row}×n_{col}
Input size of LUT: size_{LUT}
Input size of MUX: size_{MUX}

The brute-force complexity of guessing true functionality of an RSF block may be equal to a total number of functions possible from the RSF block, which may be calculated as:

$${complexity}_{tile} = ( \begin{matrix}{n}_{LUTs} \\ 1\end{matrix} ) \times {size}_{L U T} \times ( \begin{matrix}{size}_{M U X} \\ 1\end{matrix} ) \times {2}^{{2}^{s i z e} L U T} \qquad Equation 1$$

For example, a complexity for a 2×2 RSF block with 2×1 LUTs and 2×1 MUXes may be calculated according to the following:

$${n}_{r o w} = 2 ; {n}_{c o l} = 2 ; {n}_{L U T} = 4 ; {size}_{L U T} = 2 ; {size}_{M U X} = 2 ;$$

$${complexity}_{tile} = ( \begin{matrix}4 \\ 1\end{matrix} ) \times 2 \times ( \begin{matrix}2 \\ 1\end{matrix} ) \times {2}^{{2}^{2}} = 256 .$$

### Example Embodiments

According to various embodiments of the present disclosure, a RSF framework provides a versatile solution to (i) bolster the security of digital circuit designs, (ii) offer protection for scan chains, (iii) generate PUF signatures, and (iv) authenticate through hardware watermarking. In some embodiments, a dynamic reconfigurability feature of RSFs may contribute to the reduction of test power and enhancement of testability. An RSF-based framework may also offer robust protection against side channel and fault attacks, ensuring the integrity and confidentiality of digital circuit designs. Hence, RSFs may be used to provide a comprehensive security framework that addresses a wide range of potential threats.

### Scan Protection Using RSF

Scan operation may be used for testing and debugging digital circuits by allowing controlled observation and manipulation of internal states in a non-intrusive way. For example, scan operation may comprise serially shifting in new data and observing shifted-out data. Flip flops that are present in a circuit may be used to create a scan chain to enable serial shifting of data for testing and debugging purposes without interfering with the normal operation of a circuit.

FIG. 14 is a block diagram of an example scan architecture 1400. A scan enable (SE) 1402 signal may determine the operational mode of a design. MUX logics may determine which signals drive a set of flip flops 1404(A-N). During design testing, a scan input (SI) 1406 and SE 1402 may be utilized to directly drive the set of flip flops 1404(A-N) to their specified states for testability. For example, when the SE 1402 is set to ‘1’ (e.g., scan enable active), the SI 1406 may be loaded into a first flip flop (e.g., FF 1404A) on an initial clock transition. Subsequently, on a next clock cycle, a logic value stored in the first flip flop may be shifted to a following flip flop (e.g., FF 1404B) in the scan chain, while a new value may be loaded into the first flip flop. The scanning process may continue, with values being scanned in through the SI 1406 and scanned out from the last flip flop (e.g., FF 1404N) in the scan chain using the scan output (SO) 1408 signal, following a first-in-first-out (FIFO) manner. In a normal mode of operation, an original functional data input signal is passed through the MUX logic for all sequential elements.

### DFT Scan Operation

The following sequence comprises example steps of a scan operation in a digital circuit.
1. Initial State: Flip flops are initialized with some initial values.
2. Scan-in: Shift in data from a scan input port.
3. Normal Mode: Allow a circuit to operate normally without any scan input for one cycle. The flip flop values are updated accordingly.
4. Scan-out: Shift out data from a scan output port.
5. Repeat: Perform additional scan operations (e.g., steps 2 to 4) as appropriate for subsequent cycles.

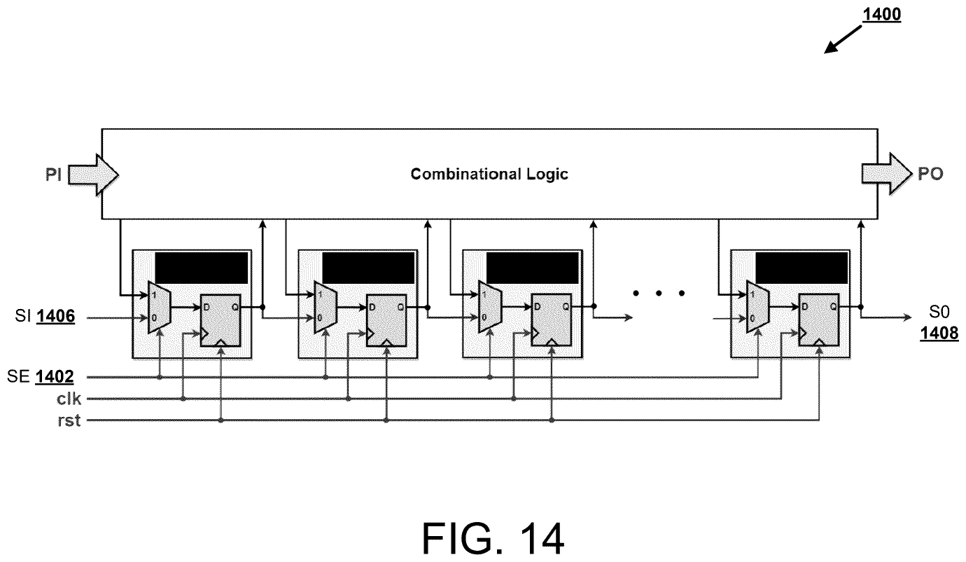

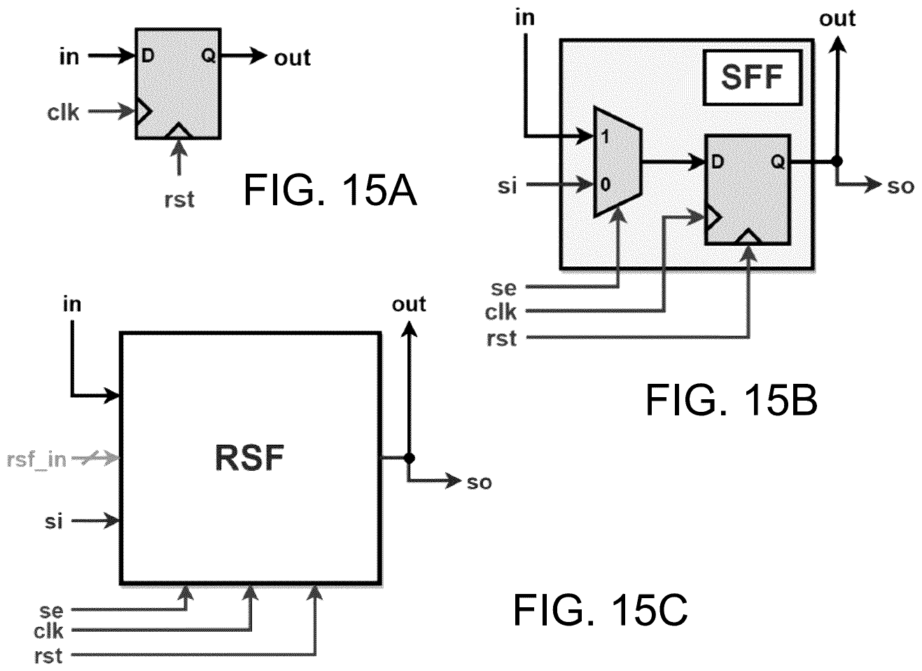

FIG. 15A is an example flip flop that may be used in a digital circuit design. Based on the aforementioned steps of a scan operation, flip flops may be modified such that a MUXed logic is added to drive the flip flops as depicted in FIG. 15B. In test mode, scan input (si) may be passed through the MUX, and while in normal mode, an original signal (in) may be passed as input to the flip flop.

FIG. 15C is an example RSF-based scan architecture in accordance with some embodiments of the present disclosure. Values in flip flops of the RSF may be scanned in and scanned out in a similar manner as described with respect to FIG. 15B except that a configurable bitstream drives the internal logic of the RSF to function accordingly. For scan operation using the RSF-based scan architecture, one or more scan flip flops may be replaced by an equivalent number of RSFs that are configured to combine scan inputs with one or more existing internal signals from a combinational logic using a bijective function (e.g., XOR/XNOR, etc.) for protecting the values in scan operation. A pre-processing step may also be performed to select one of available bijective functions that comprise internal signals from the combinational logic. Another post-processing step may be performed for applying an inverse function to obtain final values in a scan-out port.

### Bijective Function: Definition and Examples

A bijective function, also known as a bijection or a “one-to-one and onto” function, may comprise a type of function between two sets where each element in a domain is paired with a unique element in a co-domain, and each element in the co-domain is paired with a unique element in the domain. That is, a bijective function may establish a one-to-one correspondence between the elements of two sets.

Example: A XOR (⊕) function may comprise a bijective over a binary domain. The XOR function may be defined as: f(a, k)=a⊕k.
1. Injective (One-to-One): If input values are different, the XOR operation produces distinct output values. If a₁≠a₂, then f(a₁, k)+f(a₂, k).
2. Surjective (Onto): Every possible output value (e.g., 0 or 1) may be obtained by choosing an appropriate value of k. For y∈{0, 1}, there exists an a such that a⊕k=y.

The same argument may be applied to a XNOR (⊙) function which may also comprise a bijective function.

Formally: let f: A→B be a bijection. The inverse function g: B→A may be defined by: if f(a)=b, then g(b)=a. A function comprises an inverse function if and only if it is a bijection. An inverse function of the inverse function comprises the original function.

### Estimation on the Number of Possible Functions

Let a number of scan flip flops in a design=n, and a number of bijective functions under consideration=3 (e.g., XOR, XNOR, NOT). Accordingly, a total number of possible functions for a 2×1 LUT (e.g., minimal RSF) where the number of inputs is 2 and may be calculated as:

$$2 \times ( \begin{matrix}2 \\ 1\end{matrix} ) + 2 \times ( \begin{matrix}2 \\ 2\end{matrix} ) = 6.$$

For example, if the inputs are a and b, then the possible 2-input bijective functions using any of three operations (XOR, XNOR, NOT) may be the following:

$$1. a$$

$$2. {a}^{′}$$

$$3. b$$

$$4. {b}^{′}$$

$$5. a ⊕ b$$

$$6. a ⊙ b$$

Similarly, the total number of possible functions for an RSF with a 4×1 LUT configuration where the number of inputs is 4 may be calculated as:

$$2 \times ( \begin{matrix}4 \\ 1\end{matrix} ) + 2 \times ( \begin{matrix}4 \\ 2\end{matrix} ) + 2 \times ( \begin{matrix}4 \\ 3\end{matrix} ) = 28 .$$

For a generic n×1 LUT-based RSF, the number of possible functions may be calculated as:

$$2 \times ( \begin{matrix}n \\ 1\end{matrix} ) + 2 \times ( \begin{matrix}n \\ 2\end{matrix} ) + 2 \times ( \begin{matrix}n \\ 3\end{matrix} ) … + 2 \times ( \begin{matrix}n \\ n\end{matrix} ) .$$

### RSF-Based Scan Operation

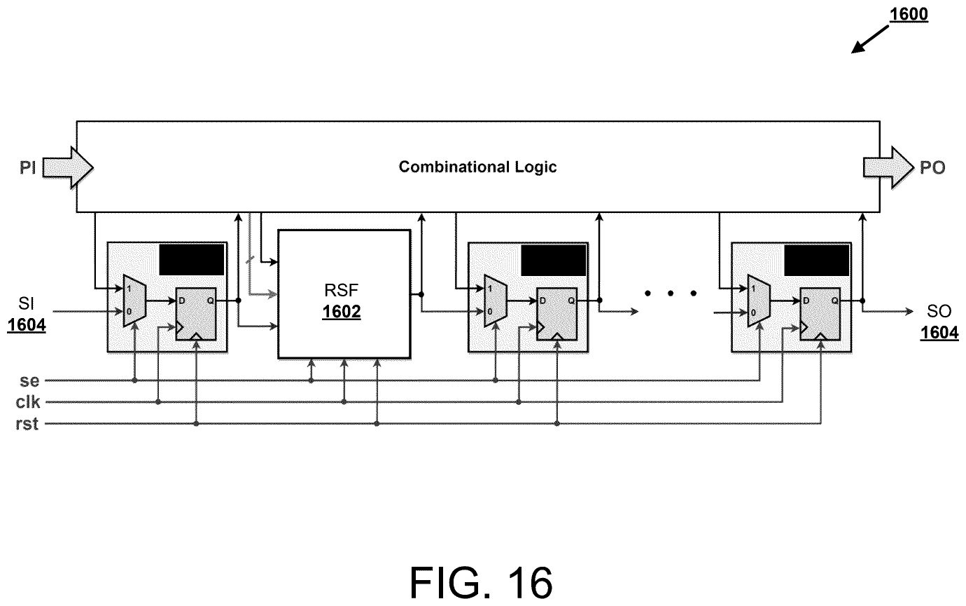

For a given test pattern X, a pre-processing step may comprise a selection of one of many available bijective functions that transforms the pattern X′ using a RSF configured by respective bitstream values. FIG. 16 depicts an example RSF-based scan architecture 1600 in accordance with some embodiments of the present disclosure. The RSF-based scan architecture 1600 leverages a RSF 1602 to protect a scan chain comprising a plurality of scan flip flops 1608(A-N). The inserted RSF 1602 may be configured to perform a bijective function (e.g., XOR or XNOR) on an output from a scan flip flop (e.g., an output that is based on the SI 1604 and one or more internal signals as selected by the scan flip flop 1608A) of the plurality of scan flip flops. The bijective function may be randomized, broadening the attacker's search space, and adds a degree of challenge for identifying a specific internal signal through reverse engineering. The bijective function may transform an original test pattern (Y) thereby generating a modified test pattern that may be propagated to subsequent flip flops (e.g., scan flip flops 1608B-N) in the scan chain and observed through the SO 1606 port. A post-processing step may apply an inverse function on the updated scan-out pattern Y′ to recover the original scan-out pattern Y. The bijective nature of the XOR/XNOR function enables the retrieval of the original value by applying the same operation, effectively neutralizing the impact of the applied function through RSF while maintaining the consistency of the scan operation.

Example: SI 1604 is XOR-ed with internal signal w, which may cause the value SI⊕w to be propagated through a series of flip flops and to SO 1604. A post-processing step may comprise employing a XOR operation, which negates the value of w to obtain the actual value of scan input SI (e.g., (SI⊕w)⊕w=SI⊕0=SI).

A RSF (e.g., RSF 1602) may be strategically placed in a circuit design by inserting the RSF at the beginning, end, or anywhere on a scan chain, while post-processing may be configured accordingly based on the position of the RSF.

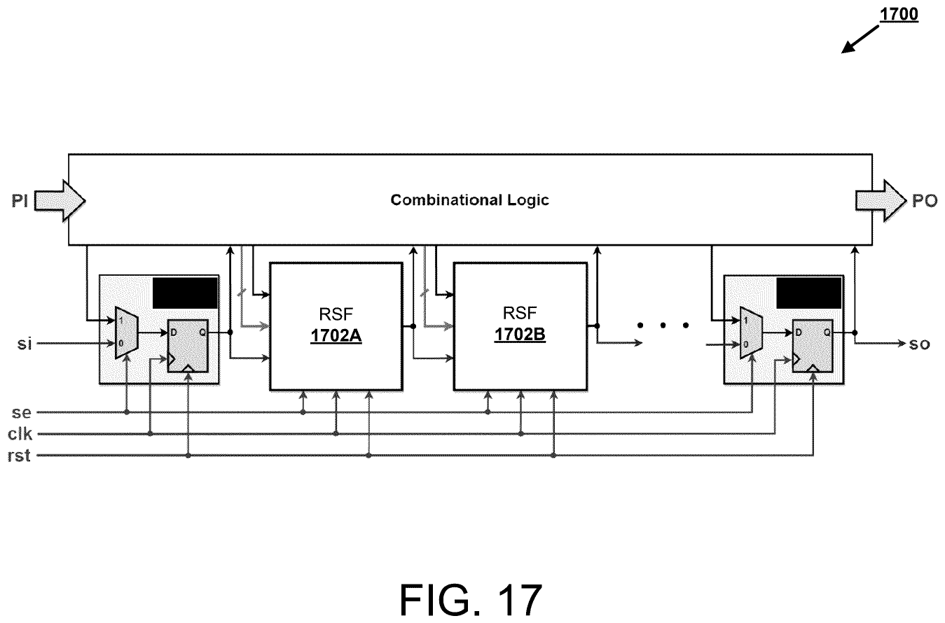

FIG. 17 depicts an example RSF-based scan architecture 1700 in accordance with some embodiments of the present disclosure. The RSF-based scan architecture 1700 may be extended for improved security by inserting additional quantities of RSFs (e.g., 1702A and 1702B) in the scan chain comprising scan flip flops 1704 (A-N).

### Test Power Improvement Using RSF

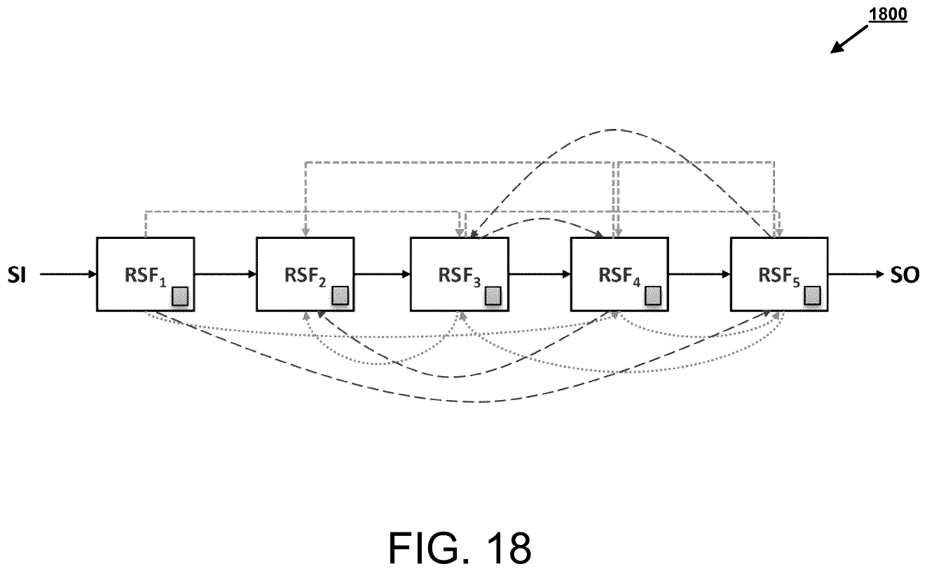

According to various embodiments of the present disclosure, an RSF-based scan protection architecture allows a designer to alter an order in which data is scanned in and out of a scan chain, thereby adding a degree of difficulty for attackers to exploit the scan order for malicious purposes. FIG. 18 is an example rearrangement of a scan chain 1800 by applying a RSF framework in accordance with some embodiments of the present disclosure. Possible scan chain orders that may be achieved with an RSF-based scan architecture are represented by the various dashed or dotted lines. As depicted in FIG. 18, example possible scan chain reordering comprises:

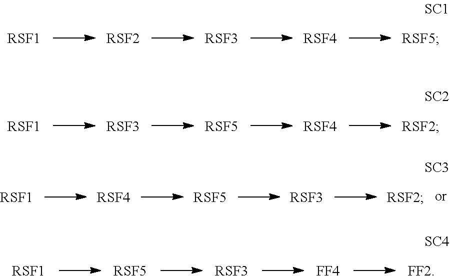

The ability of scan chain reordering via RSF may also aid in the improvement of test power by optimizing the order of scan flip flops in a scan chain. For example, an order of scan flip flops may be optimized by minimizing switching activity and power consumption during test operations. That is, by reordering scan flip flops based on factors, such as (i) proximity to primary inputs or outputs, (ii) transition probabilities, or (iii) impact on power consumption, dynamic power dissipation may be reduced during scan testing. Additionally, reordering the scan chain may help distribute test activity more evenly across a circuit, preventing localized power hotspots and reducing overall test power consumption.

### Testability Improvement Using RSF

Testability may comprise easing a testing process of a digital circuit design effectively to ensure that the digital circuit design meets one or more functional requirements and specifications. In some embodiments, design for testability (DFT) may (i) enhance the ability to detect and diagnose defects within a circuit, (ii) increase fault coverage during testing, or (iii) reduce the cost and time for test development setup. Example DFT techniques include, but are not limited to, scan chain, built-in self-test (BIST), boundary scan, etc. Controllability and observability may comprise important aspects of testability. The controllability of a digital circuit may be associated with a difficulty of setting a particular logic signal to 0 or 1, while observability for a digital circuit may be associated with a difficulty of observing a state of a logic signal. Together, controllability and observability may ensure that a digital circuit is thoroughly tested and/or evaluated to ensure functionality and reliability. According to various embodiments of the present disclosure, a RSF framework integrates various features, such as scan operations, scan chain reordering, inclusion of dummy flops, and redundancy-based fault attack protection to enhance controllability and observability, thereby improving testability. In some embodiments, a RSF is designed to work in both combinational and sequential modes and may accommodate testability measures for both logic gates (combinational) and flip flops (sequential) of a digital circuit.

### Increased Observability Using RSF

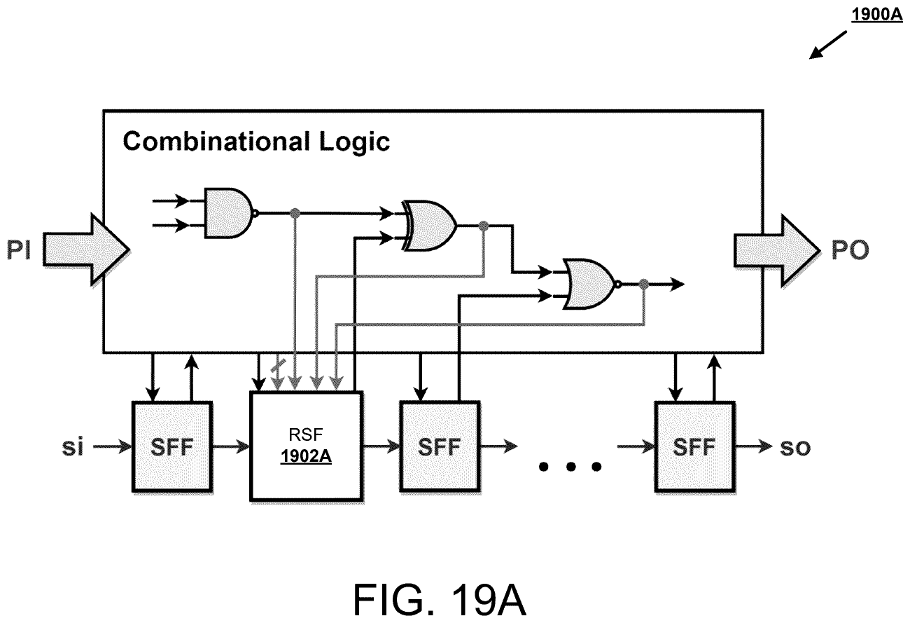

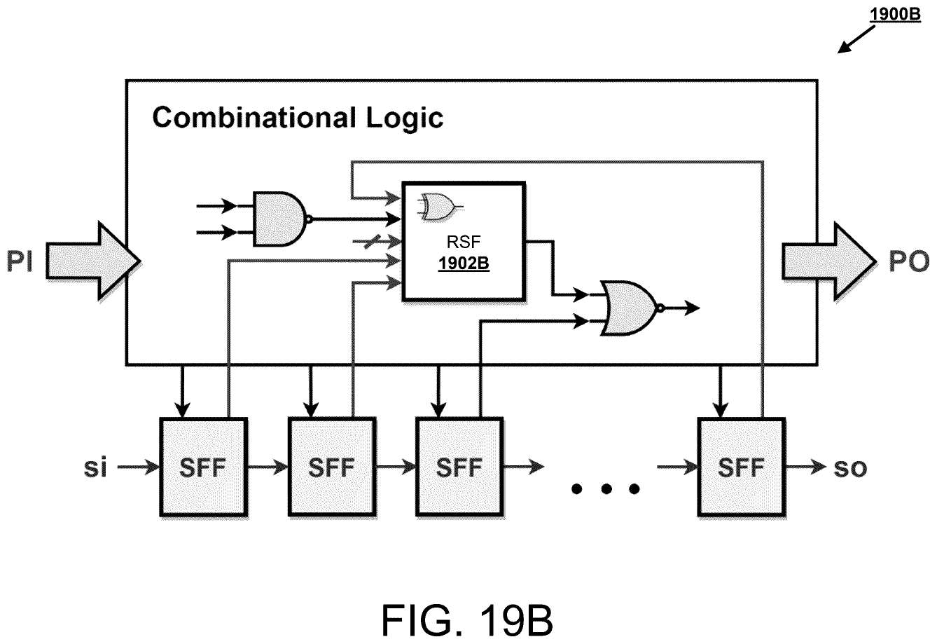

FIG. 19A is a block diagram of an example RSF architecture 1900A that may be used to improve testability by increasing observability in accordance with some embodiments of the present disclosure. Reconfigurability provided by a RSF 1902A may allow dynamic modification of circuit functionality during testing and enables runtime configurable observability of different test points to satisfy specific requirements of a circuit under test, thereby improving testability and test coverage.

Increased Controllability using RSF

FIG. 19B is a block diagram of an example RSF architecture 1900B for improving testability by increasing controllability in accordance with some embodiments of the present disclosure. A RSF 1902B may provide increased controllability through static and dynamic reconfigurability of both combinational and sequential internal signals connected to the RSF 1902B. In some embodiments, the RSF 1902B is configured through a bitstream to perform four operations: (i) constant logic 0, (ii) constant logic 1, (iii) original function, and (iv) altered function. As such, configurable controllability may enable partial or selective testing for reducing overall test time and associated costs while improving test coverage.

Additional Embodiments for Improving Testability using RSF

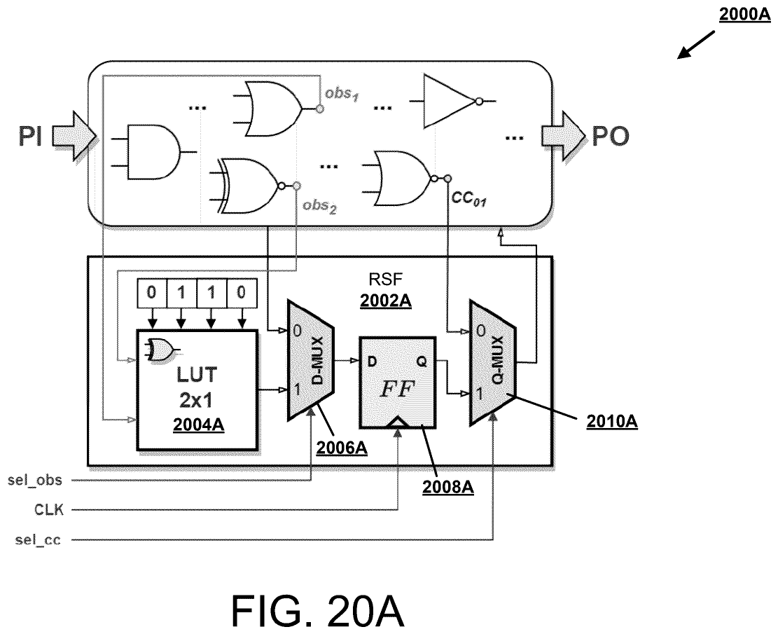

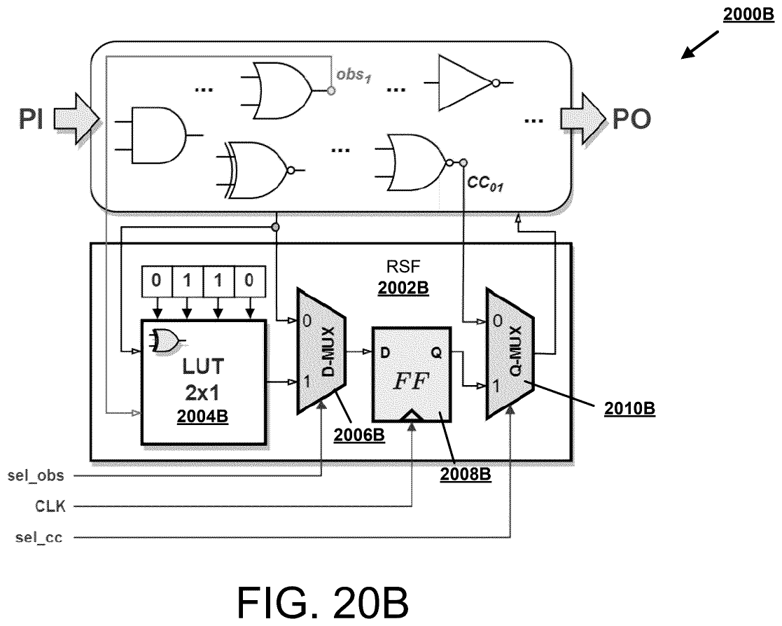

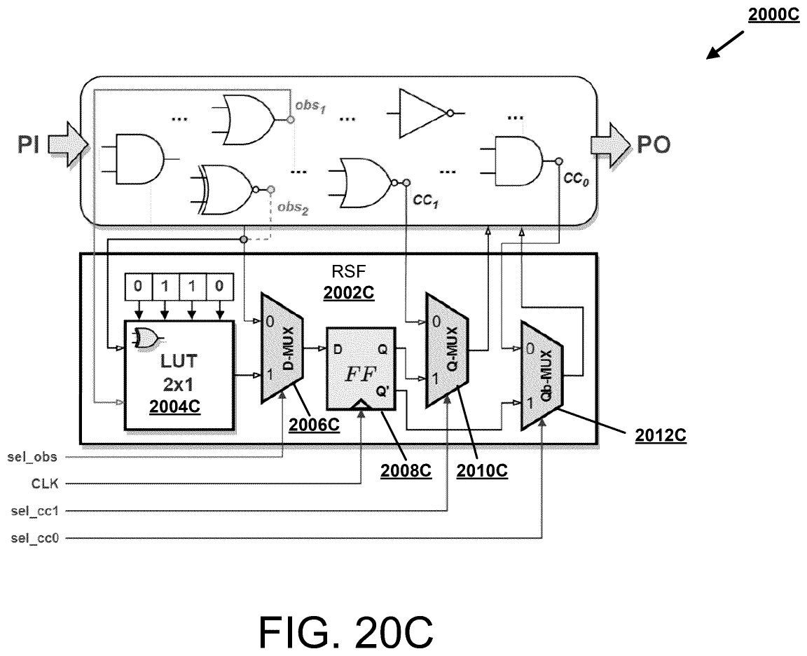

FIG. 20A is a block diagram of an example RSF architecture 2000A for improving testability in accordance with some embodiments of the present disclosure. The RSF architecture 2000A selects two less observable nets (obs₁ and obs₂) such that they are nonconflicting without contradictory values for PI and the topological order is satisfied. The selected nets are routed to RSF 2002A having LUT 2×1 (2004A) with bitstream configured as X(N)OR2 gate, followed by a 2×1 MUX (D-MUX 2006A). The original logic, previously connected to the D input of a scan FF, is now connected to the D-MUX_0 input of the D-MUX 2006A. The output of the X(N)OR2 gate is routed to the D-MUX_1 input of the D-MUX 2006A. Each D-MUX is controlled by a common select (sel_obs) line configured as an additional PI. To improve the testability further of the low controllable nets to values 0 (CC₀) or 1 (CC₁) with an additional 2×1 MUX (Q-MUX 2010A) at the Q output of the FF 2008A, with the same connected to Q-MUX_1 input of Q-MUX 2010A and one of the low controllable selected nodes to Q-MUX_0 input of Q-MUX 2010A. For each insertion, one low controllable node is selected from either CC₀ or CC₁ (CC₀₁) alternatively. Each Q-MUX may be controlled by a common select (sel_cc) line configured as an additional PI.

FIG. 20B is a block diagram of an example RSF architecture 2000B for improving testability in accordance with some embodiments of the present disclosure. The RSF architecture 2000B selects one hard-to-control net (obs₁) such that the topological order is maintained. The selected net is then routed to RSF 2002B comprising a LUT 2×1 (2004B) with bitstream configured as X(N)OR2 gate along with other input connected to the original logic, previously connected to the D input of a FF. The X(N)OR2 gate is followed by a 2×1 MUX (D-MUX 2006B) with original logic and X(N)OR2 output connected to the D-MUX_0 and D-MUX_1 inputs of the D-MUX 2006B, respectively. The select line (sel_obs) is set to value 1. Similar to RSF architecture 2000A, the testability may be improved further by including low controllable nets selected alternatively from either CC₀ or CC₁ (CC₀₁). The 2×1 Q-MUX 2010B is placed in such a way that Q-MUX_1 is connected to the Q output of the FF 2008B, while Q-MUX_0 is connected to the selected hard-to-control net driven by a common select (sel_cc) line configured as an additional PI.

FIG. 20C is a block diagram of an example RSF architecture 2000C for improving testability in accordance with some embodiments of the present disclosure. The RSF architecture 2000C may improve the testability further by inserting an additional MUX (Q-MUX 2010C) that uses the Q′ port of the design flop. The original logic, previously connected to the D input of a FF, is now connected to the DMUX_0 input of D-MUX 2006C, and X(N)OR2 gate is routed to the D-MUX_1 input of the D-MUX 2006C, driven by a common select (sel_obs) set to value 1. Two low controllable nets CC₀ (hard-to-control for value 0) and CC₁ (hard-to-control for value 1) may be selected for the RSF 2002C and connected to Qb-MUX 2012C and Q-MUX 2010C inputs respectively. Selecting two low controllable points simultaneously further enhances testability over RSF architecture 2000B (where CC0 or CC1 is selected alternatively), helping in comprehensive fault detection with more number of low controllable nets covered and reducing test patterns and time. CC1 is connected to the Q-MUX_0 input of Q-MUX 2010C and Q output from FF 2008C is connected to the Q-MUX_1 input of Q-MUX 2010C, driven by a common select (sel_cc1). CC0 is connected to the Qb-MUX_0 input of Qb-MUX 2012C and Q′ output from FF 2008C is connected to the Qb-MUX_1 input of Qb-MUX 2012C, driven by a common select (sel_cc0).

### RSF-Based Watermarking

Hardware watermarking may comprise a security technique that is used to embed unique identifiers or signatures (i.e., watermarks) into a design of electronic hardware. A primary goal of hardware watermarking may comprise providing a means of verifying the authenticity of a digital circuit design. RSFs may be used to generate a hardware watermark for a given design that is unique, robust, and hard to detect, modify, or tamper with.

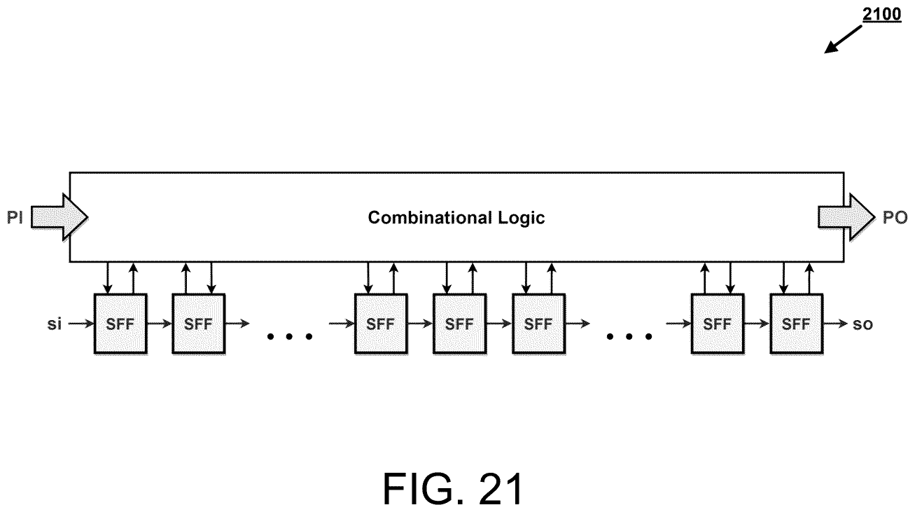

FIG. 21 is a block diagram of an example DFT scan-chain 2100 that may be modified by inserting one or more RSF blocks to generate a hardware watermark for a design associated with DFT scan-chain 2100.

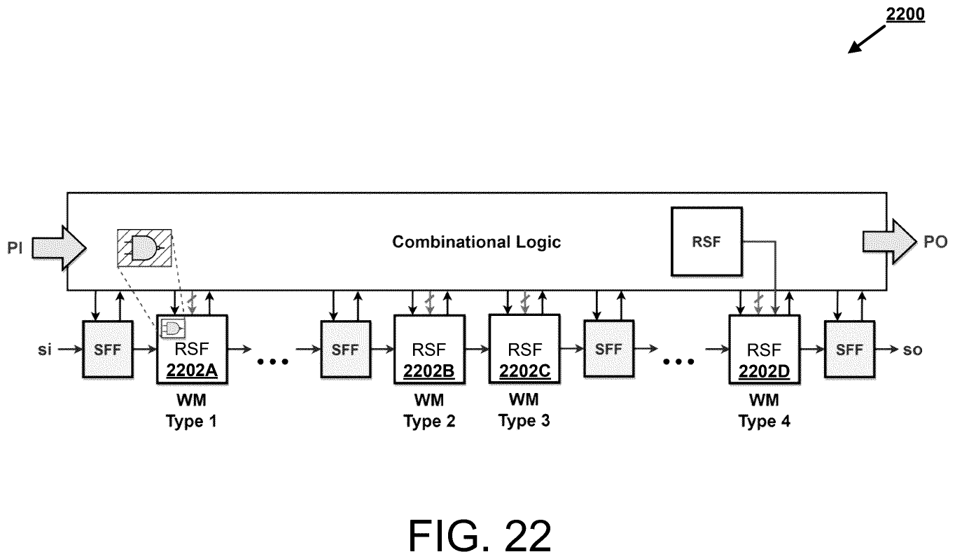

FIG. 22 is a block diagram of an example RSF-based hardware watermark generation architecture 2200. The RSF-based hardware watermark generation architecture 2200 comprises a plurality of RSF blocks 2202 that are configured to insert one of four different types of watermarks (WM) for authenticating hardware.

A WM type 1 may comprise selectively redacting combinational logic gates using LUTs in an RSF. A redacted logic may be located in the immediate fan-in of the functional input to the scan flip flop replaced by a RSF, and a redacted logic function may be used to validate the watermark.

A WM type 2 may comprise replacing existing scan flip flops with a sequential RSF (e.g., with output data flip flop used for scan chain). A watermark bit may be any logic function realized by a RSF LUT bitstream.

A WM type 3 may be similar to WM type 2 but differs by an insertion of a dummy sequential RSF into the scan chain (instead of replacing an existing scan flip flop).

A WM type 4 may be similar to WM type 1 but differs by an insertion of a dummy combinational RSF (e.g., with output data flip flop disabled) into the combinational logic block instead of redacting existing logic.

### Watermark Insertion Steps

According to various embodiments of the present disclosure, embedding a watermark comprises the following steps:
Step 1: Selecting a watermark pattern. Selecting a watermark pattern may comprise determining a unique watermark value.
Step 2: Identifying one or more target locations.

Identifying one or more target locations may comprise determining specific scan flip flops or dummy locations where the watermark will be embedded.
Step 3: Selecting a watermark type.

Selecting a watermark type may comprise determining a type of watermark to be inserted at each location.
Step 4: Initializing one or more flip flops using RSF.

Initializing one or more flip flops may comprise modifying initialization values of the one or more flip flops by applying some function (e.g., XOR) with the determined watermark. The reconfigurable feature of RSF may allow the selection of any desired function by applying a respective bitstream for generating a watermark.
Step 5: Updating a digital circuit design.

Updating a digital circuit design may comprise incorporating the modified initialization values into the digital circuit design.
Step 6: Testing and Validation

Testing and validation may comprise verifying the presence and integrity of an embedded watermark during runtime by extracting a watermark and comparing it to an expected value.

### Qualitative Analysis

For an RSF-based scan architecture with n_{RSF} RSF (e.g., comprising n_{O-RSF} replacing original scan flip flops and np-RSF additional dummy scan flip flops) inserted into an original scan-chain of length n_{SFF}, the following may be obtained:

$$len ( Original Scan Test Vector ) : {n}_{SFF}$$

$$len ( RSF - based Scan Test Vector ) : {n}_{S F F} + {n}_{D - R S F}$$

$$num ( Unique Watermarks ) : {2}^{n R S F}$$

Strong watermarking schemes may be resilient against various forms of attacks (which may reduce the confidence in the watermarks generated), including, but not limited to, the following:

Watermark forgery: An RSF-based scan architecture may prevent watermark forgery as any adversary with access to a scan-chain needs to correctly configure each of the n_{RSF} RSF embedded with the correct bitstream. Even if an adversary forges one out of 2^{nRSF} possible watermarks, the watermark may be verified by using bitstream patterns. For a single 2×1 RSF block, the brute-force complexity of guessing the bitstream may be.

$${complexity}_{tile} = ( \begin{matrix}2 \\ 1\end{matrix} ) \times ( \begin{matrix}2 \\ 1\end{matrix} ) \times ( \begin{matrix}2 \\ 1\end{matrix} ) = {2}^{{2}^{2}} = 128.$$

Thus, the total brute-force complexity for the full scan-chain with NRSF 2×1 RSF blocks may be: complexityₜₒₜₐₗ=128^{nRSF}.

Watermark modification or removal: Adversaries may try to modify or remove the watermarking architecture and the scan-chain logic. An RSF-based watermarking architecture may cause such modifications difficult via (i) addition of dummy sequential RSF in the scan-chain, (ii) addition of dummy combinational RSF, (iii) redaction of original combinational logic using RSF, and (iv) exponentially high brute-force complexity of guessing a bitstream for each RSF.

### RSF-Based PUF Signature Generation

PUFs may be used as authentication mechanisms for semiconductors. PUFs may find utility as random number generators in cryptographic applications, serve as a countermeasure against intellectual property (IP) piracy, and play an important role in chip authentication.

A memory-in-logic PUF (MeLPUF) may comprise two cross-coupled inverters such that upon device startup, the cross-coupled inverters enter into a metastable state and before settling to a value of either ‘0’ or ‘1’. It may be necessary to balance MeLPUF cells due to the likelihood that the cells may become ‘0’ or ‘1’ skewed cells.

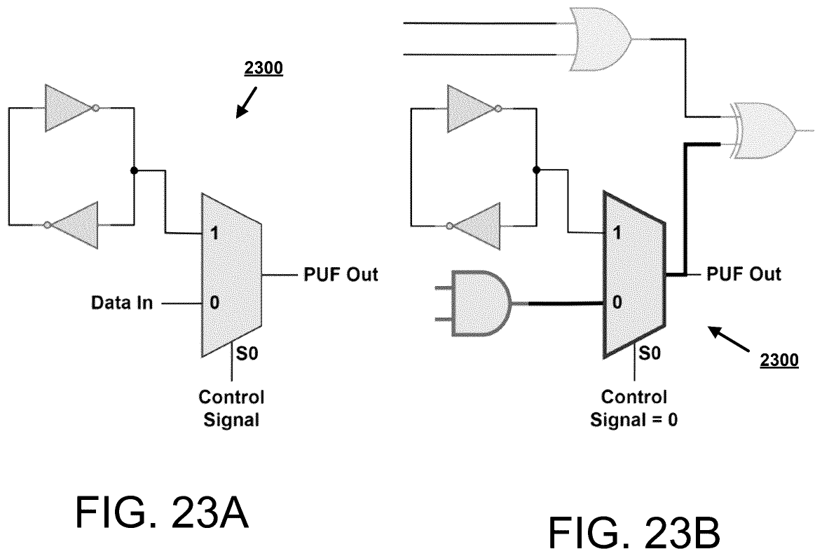

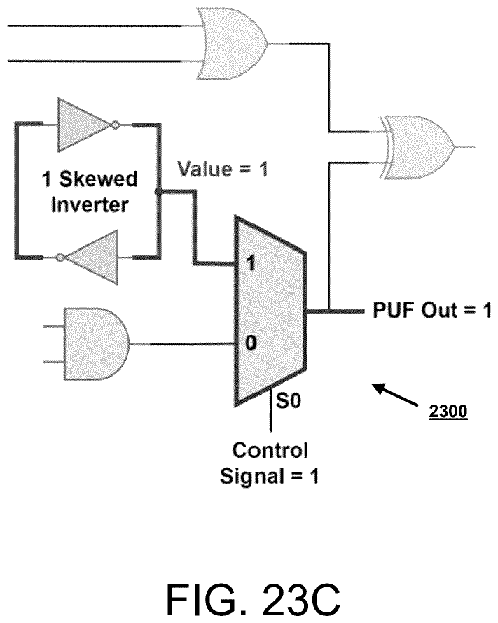

FIG. 23A depicts an example unit primitive of a MeLPUF cell 2300. Due to its relatively small footprint and lack of specialized control structure, a MeLPUF cell 2300 may be easily integrated into a combinational part of a circuit as depicted in FIG. 23B. The MeLPUF cell 2300 may comprise two modes: (a) PUF mode and (b) functional mode. The PUF mode may allow a system user to extract PUF signature values via a scan chain (e.g., FIG. 23C), and the functional mode may perform the normal operation of the system.

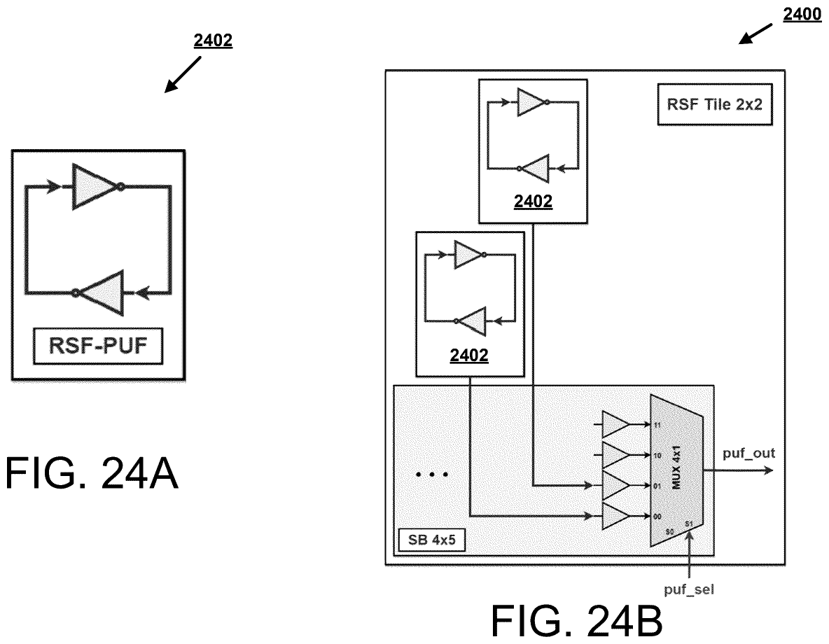

The MeLPUF's structure and functionality may be replicated with similar primitives comprising cross-coupled inverters. For example, a MeLPUF's structure and functionality may be replicated by assimilating the structure and functionality of a 1-bit PUF into a RSF primitive 2402, depicted in FIG. 24A, that uses a ReCLB in a RSF block 2×1 (e.g., RSF block 600).

FIG. 24B is an example RSF-based MeL-PUF structure 2400 in accordance with some embodiments of the present disclosure. The RSF-based MeL-PUF structure 2400 comprises two RSF primitives (2402) in a 2×2 RSF block for generating a 2-bit PUF signature.

### PUF Metrics

To calculate the performance of a MeLPUF assimilated into a RSF block, metrics, such as uniqueness, reliability, uniformity, and randomness may be used.
Uniqueness: Uniqueness may refer to an ability to identify different devices from each other when implemented with the same type and size of PUF. Uniqueness may be quantified by a Hamming distance between two PUF signatures. For an RSF-based MeLPUF, uniqueness of the PUF signature may be ensured by the distributed nature of the RSF insertion in the scan chain and an exponential number of reconfigurations possible in each RSF block.
Reliability: Reliability may comprise a measure of repeatability of an extracted PUF signature for a given challenge. The reliability of the PUF signature may be measured using an intra-chip Hamming distance between PUF signatures extracted from a same design under different operating conditions. Provided that the ReCLBs in an RSF-based MeLPUF may be correctly programmed using a configuration bitstream under any condition, and the scan-chain operation is not altered, the PUF signature may be highly reliable.
Uniformity: Uniformity may refer to a distribution of ‘0’s and ‘1’s with a sample PUF signature (response) that is generated against a given challenge. In case of an ideal PUF signature, the frequency of occurrence for both ‘0’s and ‘1’s may be equal (e.g., 50% of the total signature length).
Randomness: Randomness may refer to a balance of ‘0’s and ‘1’s of a given PUF response. Ideally, a probability distribution of either ‘0’ or ‘1’ of the response may be 0.5, and the randomness value may reach towards an ideal value of 1. The randomness of the RSF-based MeLPUF may result from random placement of RSF blocks in the scan-chain and random bitstream initialization of the non-PUF RSF blocks in a combinational logic as well as the scan-chain.

### RSF-Based Side Channel Protection

A side-channel attack may comprise a type of security attack that exploits information that is unintentionally leaked by a system or device during its normal operation. Some example types of side-channel attacks may include power analysis attacks, electromagnetic analysis attacks, timing attacks, and cache-based attacks. DPA attacks may comprise side-channel attacks that are used to extract sensitive information from cryptographic systems, such as private keys, by analyzing the power consumption patterns of the target device. DPA may rely on statistical analysis of multiple power traces to reveal patterns associated with a secret key and infer key values. A countermeasure against DPA attacks may comprise the implementation of constant-time algorithms to minimize power variations, making a system DPA-resistant.

### RSF-Based Side Channel Protection Architecture

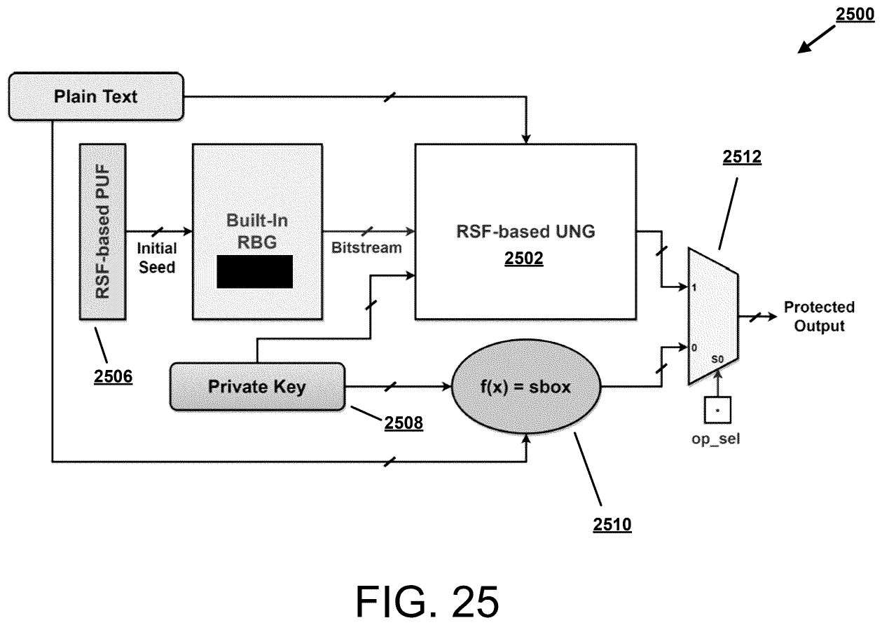

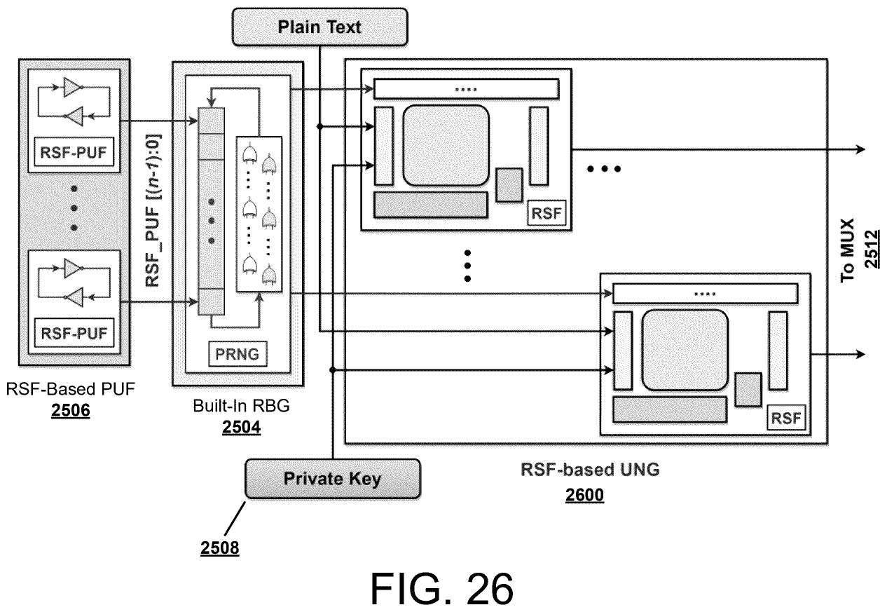

FIG. 25 is a block diagram of an example RSF-based side channel protection architecture 2500 in accordance with some embodiments of the present disclosure. The RSF-based side channel protection architecture 2500 may comprise an RSF-based UNG 2502 for minimizing power variations for different key values. The RSF-based UNG 2502 may comprise multiple RSF cells for generating outputs that contribute to a dynamic power of a whole digital circuit design, such that a key application does not create a power trace that is distinguishable from an average power trace. FIG. 26 is a block diagram of an example RSF-based UNG 2600 in accordance with some embodiments of the present disclosure. The RSF-based UNG 2600 is an example of the RSF-based UNG 2502 in FIG. 25.

Referring back to FIG. 25, a configuration bitstream for the RSF-based UNG 2502 may be generated from a built-in random bitstream generator (RBG) 2504. The built-in RBG 2504 may comprise a maximum period non-linear feedback register (NLFSR) that is initialized using an RSF-based PUF 2506. A cryptographic operation, f(x)=sbox, 2510 may represent the Rijndael substitution box used in the advanced encryption standard (AES) cryptographic algorithm. A plaintext and a correct private key 2508 may be applied to both the RSF-based UNG 2502 and the cryptographic operation, f(x)=sbox, 2510. The outputs from the RSF-based UNG 2502 and the cryptographic operation, f(x)=sbox, 2510 may then be directed through a MUX 2512.

A primary objective of the RSF-based side channel protection architecture 2500 may comprise mitigating side-channel attacks, specifically by maintaining an average or constant power value even in the presence of an incorrect key to reduce the variations and fluctuations that may be correlated to a correct key. That is, the cryptographic operation, f(x)=sbox, 2510 implementation may incur more power during an application of a correct private key compared to incorrect key applications. As such, the RSF-based UNG 2502 may randomize power consumption for different key values by producing random power values based on a random bitstream from the RBG. The RSF-based UNG 2502 may introduce controlled randomness that is unique to a specific implementation due to the RSF-based PUF 2506, and an application of same inputs to both paths may ensure the synchronization between the outputs of the RSF-based UNG 2502 and the cryptographic operation, f(x)=sbox, 2510. The MUX 2512 may facilitate a selection of a protected output based on specific criteria and may be disabled by setting the op_sel bit to ‘0’ to enable true functionality.

### RSF-Based Fault Attack Protection

A fault attack may comprise a type of attack in which an adversary intentionally induces faults or errors into a system to manipulate its behavior, extract sensitive information, or compromise its security. As such, fault attacks may exploit vulnerabilities arising from hardware or software flaws, environmental conditions, or intentional interventions. Protection mechanisms against fault attacks may be designed to detect, mitigate, and recover from the effects of intentionally induced faults. Some common protection mechanisms against fault attacks include (i) error detection and correction codes, (ii) redundancy and majority voting, (iii) secure boot and code integrity checks, (iv) secure key storage and management, and (v) hardware redundancy and diversity.

### RSF-Based Fault Attack Protection Using Redundancy and Majority Voting

Creating structural variants of a function in a design may introduce function diversification and may offer several benefits in terms of security, robustness, and resistance against diverse attacks due to redundancy. Triple modular redundancy (TMR) may comprise a specific form of redundancy where three identical modules may operate concurrently, and a result is determined by majority voting. TMR may be used to help identify the presence of faults and mitigate fault impact by selecting a correct result through majority voting.

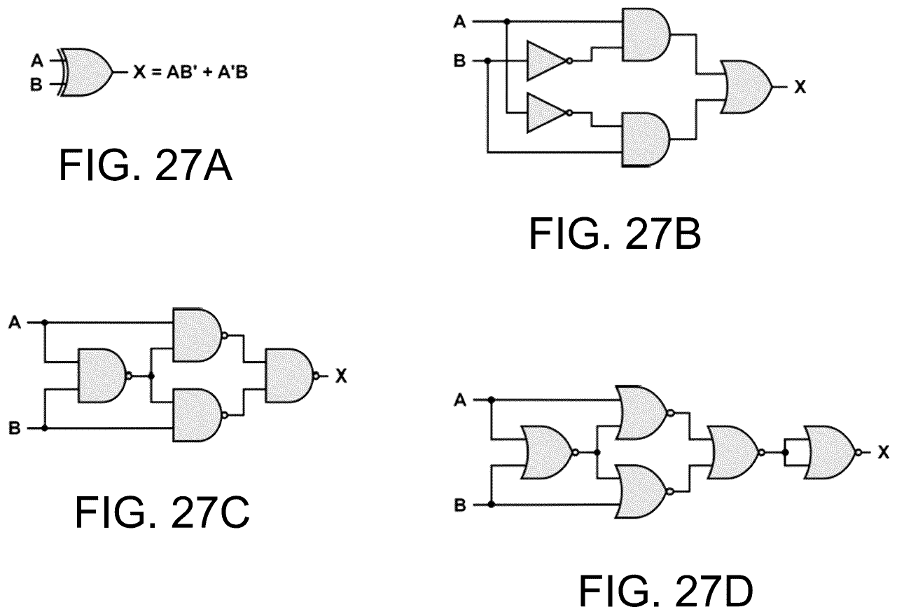

FIG. 27A through FIG. 27D depict example structural variants for a XOR function created using different logic gates without altering the original functionality (e.g., X=A⊕B=ĀB+AB̅).

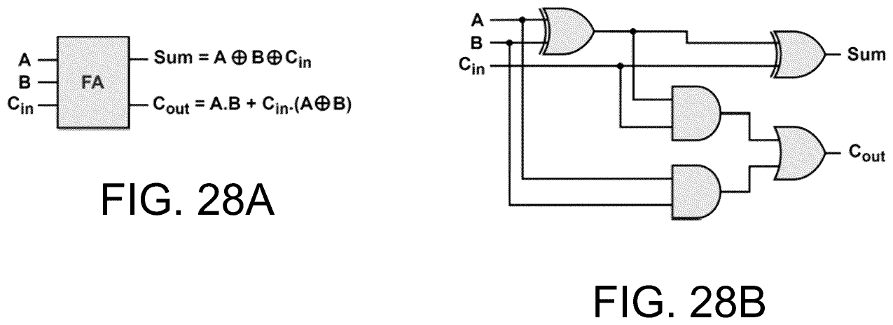

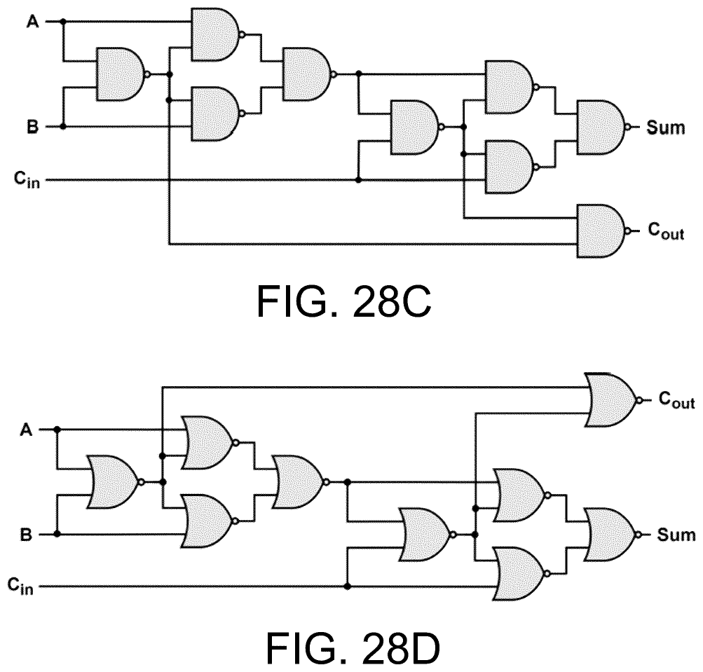

FIG. 28A through FIG. 28D depict example structural variants of a full adder circuit.

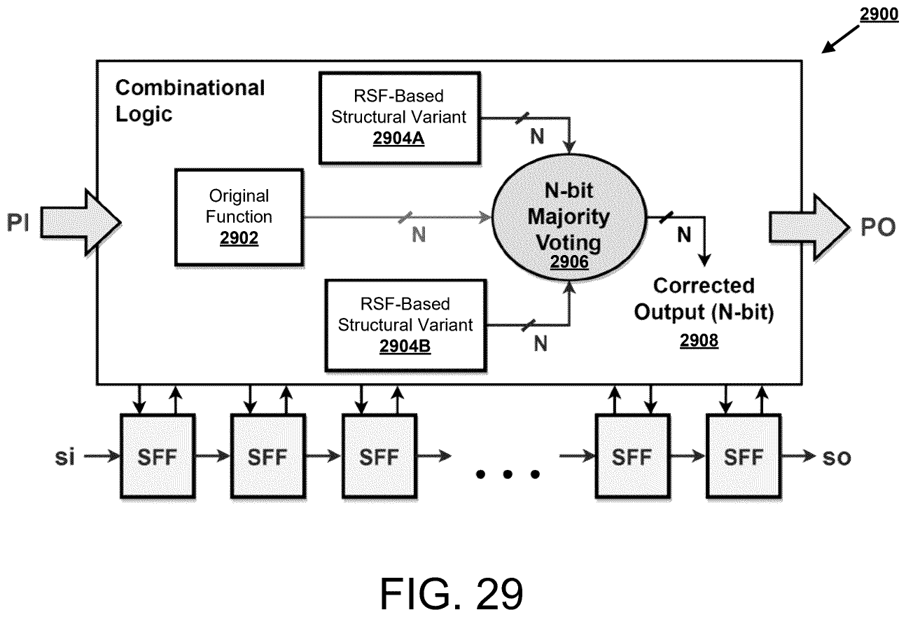

FIG. 29 is a block diagram of an example RSF-based fault attack protection architecture 2900 in accordance with some embodiments of the present disclosure. The RSF-based fault attack protection architecture 2900 may duplicate critical functions through RSF-based structural variants 2904A and 2904B and employ a majority voting function 2906 to obtain corrected output 2908 of an original function 2902.

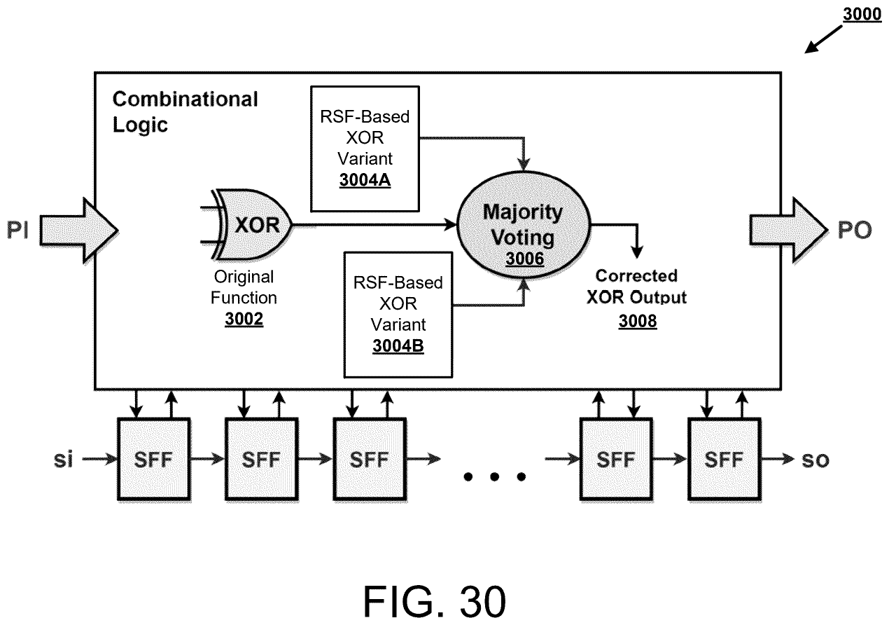

FIG. 30 is a block diagram of an example RSF-based fault attack protection architecture 3000 in accordance with some embodiments of the present disclosure. The RSF-based fault attack protection architecture 3000 incorporates duplication of a critical XOR original function 3002 using NAND and NOR through configurable RSF-based XOR variants 3004A and 3004B followed by a majority voting function 3006 to select a correct XOR output 3008.

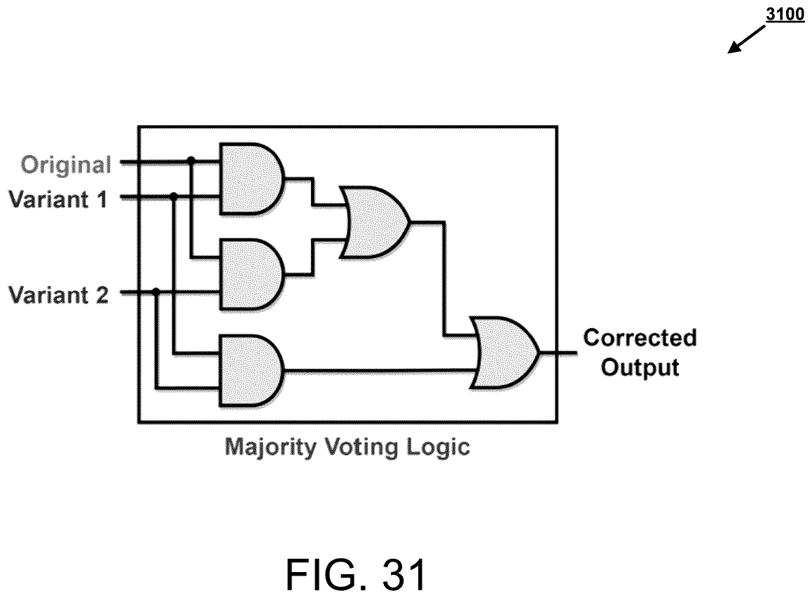

FIG. 31 is an example majority voting logic 3100 in accordance with some embodiments of the present disclosure. A RSF may additionally offer runtime reconfigurability, allowing the selection of a given function by applying corresponding bitstream values. As such, security may be enhanced by preventing attackers from determining the rareness and signal probability of nodes, as well as limiting observability thereby contributing to improved protection against hardware Trojan attacks.

### Example Integration of RSF in IC Design Flow Operations

Various embodiments of the present disclosure describe steps, operations, processes, methods, functions, and/or the like for integrating RSF in an IC design flow along with verification of available security features.

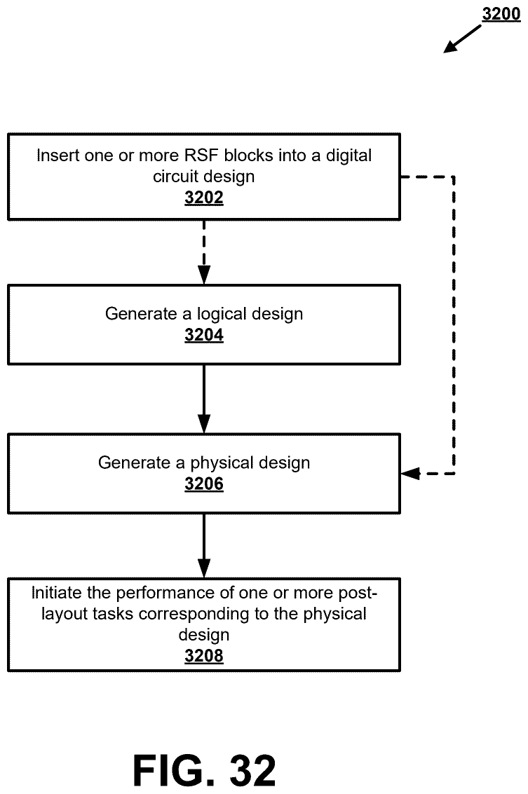

FIG. 32 presents a flowchart of an example process 3200 for integrating RSF-based security features into stages of an IC design flow according to some embodiments of the present disclosure.

In some embodiments, the process 3200 begins at step/operation 3202 when the computing system 101 inserts one or more RSF blocks into a digital circuit design. The one or more RSF blocks may be placed in a digital circuit design at the beginning, end, or anywhere on combinational logic and/or sequential logic network. The digital circuit design may comprise a digital design associated with an IC, such as an ASIC, FPGA, PLA, etc. In some embodiments, the one or more RSF blocks are inserted into the digital circuit design either during a logical design phase (e.g., step/operation 3204) or a physical design phase (e.g., step/operation 3206).

In some embodiments, at step/operation 3204, the computing system 101 generates a logical design based on the digital circuit design, and optionally, the one or more RSF blocks. In some embodiments, generating the logical design comprises (i) defining design specifications, (ii) generating a register transfer level (RTL) behavioral description (e.g., using hardware description languages, such as Verilog/SystemVerilog/VHDL), (iii) synthesizing and performing scan insertion, (iv) performing functional and/or formal verification, and (v) performing static timing analysis.

In some embodiments, at step/operation 3206, the computing system 101 generates a physical design based on the logical design, and optionally, the one or more RSF blocks. Generating the physical design may comprise transforming the logical design into a physical layout which aids in manufacturing of the digital circuit design. In some embodiments, generating the physical design comprises tasks, such as floor planning, placement and routing, design rule check, and creating a graphic design system file format (e.g., GDSII) for fabrication.

Accordingly, via steps/operations 3204 or 3206, a RSF may be integrated into an original design at (i) the RTL level, (ii) the gate-level netlist during the synthesis stage, or (iii) at the layout level during the floor planning stage in the physical design phase.

In some embodiments, at step/operation 3208, the computing system 101 initiates the performance of one or more post-layout tasks corresponding to the physical design. The one or more post-layout tasks may include fabrication, packaging, and testing before a physical device (e.g., IC) is delivered to an end user. RSF-based security features (via insertion of the one or more RSF blocks) may help improve post-silicon validation and testing, as well as protect a digital circuit generated based on the physical design against confidentiality, integrity, and availability attacks at untrusted third-party facilities and once the digital circuit is available in the market post-deployment. The RSF-based security features may be verified alongside original logic in a standard design flow. For example, during a testing phase after the packaging, RSF-based scan protection may be provided to thwart any malicious intent by adversaries at untrusted third-party facilities. The usage of RSF may also provide testability improvement and reduction of test power to enhance post-silicon validation. Once the designed digital circuit is available to end users (and adversaries), the disclosed secure authentication measures, for example, watermark and PUF signature generated using an RSF-based framework, may keep the digital circuit secure against adversaries post-deployment. Additionally, comprehensive validation procedures may be employed to ensure the efficacy of an RSF-based protection framework against side-channel attacks and fault attacks. In some embodiments, a RSF framework may be compatible with commercial EDA tool flows (e.g., from Synopsys/Cadence/Siemens (for ASIC) and AMD/Intel (for FPGA)).

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

1. A computer-implemented method comprising:
inserting, by one or more processors, one or more reconfiguration security fabric (RSF) blocks into a digital circuit design, wherein (i) a RSF block of the one or more RSF blocks comprises a reconfigurable logic block (ReCLB), one or more programmable input/output (PIO) routers, and a switch box, and (ii) the ReCLB, the one or more PIO routers, and the switch box are programmable by a configuration bitstream;
generating, by the one or more processors, a logical design based on the digital circuit design and the one or more RSF blocks;
generating, by the one or more processors, a physical design based on the logical design; and
initiating, by the one or more processors, a performance of one or more post-layout tasks corresponding to the physical design.

2. The computer-implemented method of claim 1, wherein inserting the one or more RSF blocks into the digital circuit design comprises inserting the one or more RSF blocks into a location within a combinational logic or sequential logic network.

3. The computer-implemented method of claim 1, wherein generating the logical design comprises:
defining one or more design specifications;
generating a register transfer level (RTL) behavioral description;
synthesizing and performing a scan insertion;
performing functional or formal verification; and
performing static timing analysis.

4. The computer-implemented method of claim 1, wherein generating the physical design comprises transforming the logical design into a physical layout.

5. The computer-implemented method of claim 1, wherein generating the physical design comprises one or more of floor planning, placement and routing, design rule check, or creating a graphic design system file format for fabrication.

6. The computer-implemented method of claim 1, wherein the one or more post-layout tasks comprises one or more of fabrication, packaging, or testing of a physical device.

7. The method of claim 1, wherein the one or more RSF blocks comprise runtime reconfigurability that allows selection of one or more functions that limit rareness and signal probability determination of nodes.

8. A reconfiguration security fabric (RSF) comprising:
a reconfigurable logic block (ReCLB) comprising a plurality of lookup tables (LUTs);
one or more programmable input/output (PIO) routers comprising a plurality of multiplexers (MUXs) that determine routing of data to or from the ReCLB;
a switch box that is configured to route a plurality of outputs from the plurality of LUTs to the one or more PIO routers; and
a configuration bitstream that is communicatively coupled to the ReCLB, the one or more PIO routers, and the switch box, wherein functionality of the ReCLB, the one or more PIO routers, and the switch box is altered by shifting the configuration bitstream.

9. The RSF of claim 8, wherein a MUX of the plurality of MUXs is configured to:
select a signal from serial input data based on the configuration bitstream; and
route the signal to the ReCLB.

10. The RSF of claim 8, wherein the configuration bitstream comprises a daisy-chained shift register with a serial bit input and a serial bit output.

11. The RSF of claim 8, wherein the configuration bitstream is configured to provide (i) a combinational mode that generates a functional output based on combinational logic, or (ii) a sequential mode that generates scan outputs corresponding to output data provided to a data flip flop for sequential logic or scan/test mode operation.

12. The RSF of claim 8, wherein a PIO router of the one or more PIO routers is configured to route output signals of the RSF.

13. The RSF of claim 8 further comprising a physical unclonable function (PUF), wherein the RSF is configured in a memory-based PUF that is configured to generate a PUF signature.

14. The RSF of claim 8 further comprising a physical unclonable function (PUF), wherein the RSF is configured in an RSF-based side-channel protection system, wherein the RSF-based side-channel protection system comprises an RSF-based universal noise generator (UNG) and an RSF-based PUF.

15. The RSF of claim 8, wherein the RSF is configured in an RSF-based fault attack protection system, wherein the RSF-based fault attack protection system comprises a plurality of RSF-based structural variants and a majority voting function.

16. A reconfiguration security fabric (RSF)-based scan architecture comprising:
a combinational logic block;
a scan chain comprising a plurality of scan flip flops that is coupled to the combinational logic block; and
one or more RSFs that are inserted in the scan chain, wherein a RSF of the one or more RSFs is configured to:
(i) receive a first output from a first scan flip flop of the plurality of scan flip flops,
(ii) generate a second output based on the first output, and
(iii) provide the second output to a second scan flip flop of the plurality of scan flip flops that is subsequent to the first scan flip flop.

17. The RSF-based scan architecture of claim 16, wherein the RSF comprises a configurable lookup table (LUT) that is configured to implement a bijective function, and the RSF is further configured to:
generate the second output by performing the bijective function on the first output; and
provide the second output to the second scan flip flop of the plurality of scan flip flops.

18. The RSF-based scan architecture of claim 16, wherein the RSF is configured to reorder one or more scan flip flops of the plurality of scan flip flops based on one or more of (i) proximity to primary inputs or outputs, (ii) transition probabilities, or (iii) impact on power consumption.

19. The RSF-based scan architecture of claim 16, wherein the one or more RSFs are configured to insert a watermark associated with authenticating hardware.

20. The RSF-based scan architecture of claim 19, wherein the watermark comprises at least one of (i) selectively redacting one or more combinational logic gates of the combinational logic block, (ii) replacing one or more scan flip flops with a sequential RSF, (iii) inserting a dummy sequential RSF into the scan chain, or (iv) inserting a dummy combinational RSF into the combinational logic block.
